(19) United States
(12) Patent Application Publication
(10) Pub. No.: US 2024/0138227 A1
(43) Pub. Date: Apr. 25, 2024

(54) DISPLAY DEVICE WITH STACKED COLOR FILTERS

(71) Applicant: SAMSUNG DISPLAY CO., LTD., YONGIN-SI (KR)

(72) Inventors: KWANG SOO BAE, YONGIN-SI (KR); GEE-BUM KIM, YONGIN-SI (KR); BOKWANG SONG, YONGIN-SI (KR); MIN OH CHOI, YONGIN-SI (KR); SOO YEONG HONG, YONGIN-SI (KR)

(21) Appl. No.: 18/468,578

(22) Filed: Sep. 14, 2023

(30) Foreign Application Priority Data
Oct. 20, 2022 (KR) 10-2022-0136676

(51) Int. Cl. H10K 59/38; H10K 59/40

(52) U.S. Cl. CPC H10K 59/38; H10K 59/40

(57) ABSTRACT

A display device has a base layer, including light-emitting regions of first to third colors, respectively, at least one light-receiving region, and a non-light-emitting region surrounding the light-emitting regions and the at least one light-receiving region; a display element layer disposed on the base layer, including first to third light-emitting elements each corresponding to the light-emitting regions of the first to third colors, respectively, and a light-receiving element corresponding to the at least one light-receiving region; and a color filter layer disposed on the display element layer and including first to third color filters, first regions each having one color filter corresponding to a respective one of the first to third color filters disposed therein and each overlapping a respective one of the first to third color light-emitting regions, and a second region in which two different color filters of the first to third color filters are stacked.

### CROSS-REFERENCE

This U.S. non-provisional patent application claims priority under 35 U.S.C. § 119 to Korean Patent Application No. 10-2022-0136676, filed in the Korean Intellectual Property Office (KIPO) on Oct. 21, 2022, the entire disclosure of which is incorporated by reference.

### FIELD

The present disclosure relates to display devices, and more particularly relates to display devices with stacked color filters configured for recognizing biometric information.

### DISCUSSION

Display devices serve a multitude of functions, such as image display to provide users with information and/or user input detection, to facilitate interactive communications with users. Some display devices may also detect biometric information of users. Biometric information recognition methods may include a capacitance method for detecting changes in capacitance formed between electrodes, an optical method for detecting incident light using an optical sensor, and an ultrasonic method for detecting vibration using a piezoelectric material. When optical sensors are included, it may be desirable to enhance performance of biometric information recognition by blocking noise such as that caused by external light.

### SUMMARY

The present disclosure may provide display devices obtained through simplified manufacturing processes. The present disclosure may provide display devices having optimized sensing performance from a sensor for biometric information recognition. The present disclosure may provide display devices having reduced visibility defects.

An embodiment of the inventive concept provides a display device comprising: a base layer, including light-emitting regions of first to third colors, respectively, at least one light-receiving region, and a non-light-emitting region surrounding the light-emitting regions and the at least one light-receiving region; a display element layer disposed on the base layer, including first to third light-emitting elements each corresponding to the light-emitting regions of the first to third colors, respectively, and a light-receiving element corresponding to the at least one light-receiving region; and a color filter layer disposed on the display element layer and including first to third color filters, wherein the color filter layer includes first regions each having one color filter corresponding to a respective one of the first to third color filters disposed therein and each overlapping a respective one of the first to third color light-emitting regions, a second region in which two different color filters of the first to third color filters are stacked, and a third region in which three different color filters of the first to third color filters are stacked, wherein the third region surrounds the light-receiving region when viewed on a plane.

In an embodiment, in the third region, the second and third color filters are stacked on the first color filter.

In an embodiment, the display device may be configured wherein in each of the second and third regions, the third color filter is disposed on the second color filter, wherein in a thickness direction of the base layer, a distance from the base layer to the third color filter in the third region is greater than a distance from the base layer to the third color filter in the second region.

In an embodiment, the display device may be configured wherein the color filter layer overlapping the non-light-emitting region between the light-receiving region and the light-emitting region adjacent to the light-receiving region among the first to third color light-emitting regions is thicker than the color filter layer overlapping the non-light-emitting region between adjacent light-emitting regions among the first to third color light-emitting regions.

In an embodiment, the display device may be configured wherein the second region overlaps each of the non-light-emitting region disposed between the first and second light-emitting regions, the non-light-emitting region disposed between the first and third color light-emitting regions, and the non-light-emitting region disposed between the second and third color light-emitting regions.

In an embodiment, the display device may be configured wherein in the second region, the two color filters among the first to third color filters are the second and third color filters.

In an embodiment, the display device may be configured wherein the first color filter comprises: a first portion overlapping the light-receiving region; and a second portion overlapping the first light-emitting region.

In an embodiment, the display device may include an input sensing layer including a sensing electrode overlapping the non-light-emitting region and at least one insulating layer covering the sensing electrode, and disposed between the display element layer and the color filter layer, wherein the sensing electrode overlaps each of the second and third color filters.

In an embodiment, the display device may be configured wherein the sensing electrode overlapping the non-light-emitting region overlaps the first portion in each space between the light-receiving region and the first color light-emitting region, between the light-receiving region and the second color light-emitting region, and between the light-receiving region and the third color light-emitting region.

In an embodiment, the display device may be configured wherein the sensing electrode overlapping the non-light-emitting region non-overlaps the second portion in each space between the first and second light-emitting regions, between the first and third light-emitting regions, and between the second and third light-emitting regions.

In an embodiment, the display device may be configured wherein the color filter layer overlapping the non-light-emitting region is entirely in contact with an insulating layer disposed on an uppermost side of the at least one insulating layer.

In an embodiment, the display device may be configured wherein each of the first to third color light-emitting regions is in plurality, wherein the second and third color light-emitting regions are alternately arranged in each of a first direction and a second direction perpendicular to the first direction, and wherein the first color light-emitting regions comprise a first sub-light-emitting region and a second sub-light-emitting region, the first and second sub-light-emitting regions are alternately arranged in each of the first and second directions, and each of the first and second sub-light-emitting regions is disposed between the second and third color light-emitting regions spaced apart in the second direction.

In an embodiment, the display device may be configured wherein one first sub-light-emitting region, one second sub-light-emitting region, one second color light-emitting region, and one third color light-emitting region define a unit light-emitting region, wherein one light-receiving region is disposed within the unit light-emitting region, and wherein the light-receiving region is disposed between the first and second sub-light-emitting regions spaced apart in the first direction.

In an embodiment, the display device may be configured wherein the second portion comprises a first sub-portion overlapping the first sub-light-emitting region, and a second sub-portion overlapping the second sub-light-emitting region, which are spaced apart in the first direction with the first portion therebetween, and wherein the first and second sub-portions are in the form of a single body with the first portion.

In an embodiment, the display device may be configured wherein in the second color filter, a first opening overlapping the light-receiving region, a second opening overlapping the first color light-emitting region, and a third opening overlapping the third color light-emitting region are defined.

In an embodiment, the display device may be configured wherein in the third color filter, a fourth opening overlapping the light-receiving region and corresponding to the first opening, a fifth opening overlapping the first color light-emitting region and corresponding to the second opening, and a sixth opening overlapping the second color light-emitting region are defined.

In an embodiment, the display device may be include a sensing electrode disposed between the display element layer and the color filter layer and overlapping the non-light-emitting region, wherein the sensing electrode has first to third mesh openings respectively corresponding to the first to third color light-emitting regions defined therein, and wherein on a cross-section, the first mesh opening has a greater width than each of the second and fifth openings, the second mesh opening has a greater width than the sixth opening, and the third mesh opening has a greater width than the third opening.

In an embodiment, the display device may be configured wherein a fourth mesh opening corresponding to the light-receiving region is defined in the sensing electrode, and wherein on a cross-section, the fourth mesh opening has a greater width than each of the first and fourth openings.

In an embodiment, the display device may be configured wherein when viewed on a plane, the first color light-emitting region has a smaller area than each of the second and third color light-emitting regions.

In an embodiment, the display device may include a planarization layer disposed on the color filter layer to cover the color filters; and a window disposed on the planarization layer.

### BRIEF DESCRIPTION OF THE DRAWINGS

The accompanying drawings are included to provide a further understanding of the inventive concept, and are incorporated in and constitute a part of this disclosure. The drawings illustrate embodiments of the inventive concept and, together with the description, serve to explain principles of the inventive concept by way of example. In the drawings:

FIG. 1 is a perspective view diagram of a display device according to an embodiment of the inventive concept;

FIG. 2 is a cross-sectional view diagram of a display device according to an embodiment of the inventive concept;

FIG. 3 is a block diagram of a display device according to an embodiment of the inventive concept;

FIG. 4 is a plan view diagram enlarging a portion of a display device according to an embodiment of the inventive concept;

FIG. 5 is a circuit diagram of a pixel and a sensor according to an embodiment of the inventive concept;

FIG. 6 is a cross-sectional view diagram of a display panel taken along line I-I′ of FIG. 4 according to an embodiment of the inventive concept;

FIGS. 7A to 7C are plan view diagrams showing some components of a display device according to an embodiment of the inventive concept;

FIG. 8A is a cross-sectional view diagram of a display device taken along line II-II′ of FIG. 7A according to an embodiment of the inventive concept;

FIG. 8B is a cross-sectional view of a display device taken along line III-III′ of FIG. 7A according to an embodiment of the inventive concept;

FIG. 8C is a cross-sectional view diagram of a display device taken along line IV-IV′ of FIG. 7A according to an embodiment of the inventive concept;

FIG. 9A is a cross-sectional view diagram of a display device according to an embodiment of the inventive concept;

FIG. 9B is a cross-sectional view diagram of a display device according to an embodiment of the inventive concept in which a portion of FIG. 9A is enlarged;

FIG. 10A is a cross-sectional view diagram of a display device according to an embodiment of the inventive concept; and

FIG. 10B is a cross-sectional view diagram of a display device according to a comparative example.

### DETAILED DESCRIPTION

Embodiments of the inventive concept are described below by way of non-limiting examples. It shall be understood that various changes in form and details may be implemented by those of ordinary skill in the pertinent art based on the teachings herein.

In the description that follows, when an element (or a region, a layer, a portion, or the like) is referred to as “being on”, “connected to” or “coupled to” another element, it may be directly disposed on, connected or coupled to the other element, or intervening elements may be disposed therebetween.

Like reference numerals may refer to like elements. In addition, in the drawings, the thickness, the ratio, and/or the dimensions of elements may be exaggerated for an effective description of technical contents. The term “and/or” may include any or all combinations of one or more of the associated terms.

It shall be understood that, although the terms first, second, and the like may be used herein to describe various elements, these elements should not be limited by these terms. These terms are only used to distinguish one element from another element. For example, a first element may be referred to as a second element, and similarly, a second element may be referred to as a first element without departing from the teachings of the present disclosure. The singular forms are intended to include the plural forms as well, unless the context clearly indicates otherwise.

Also, terms of “below”, “on a lower side”, “above”, “on an upper side”, or the like may be used to describe the relationships of the components shown in the drawings. The terms are used in a relative sense and are described with reference to the direction indicated in the drawings.

It shall be understood that the terms “comprise” or “have” are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined, all terms (including technical and scientific terms) used herein have the same meanings as commonly understood by those of ordinary skill in the art to which the present disclosure pertains. In addition, terms, such as those defined in commonly used dictionaries, should be interpreted as having meanings that are consistent with their meanings in the context of the relevant art, and should not be interpreted in an idealized or overly formal sense unless expressly so defined herein.

Hereinafter, illustrative embodiments of the inventive concept will be described with reference to the accompanying drawings.

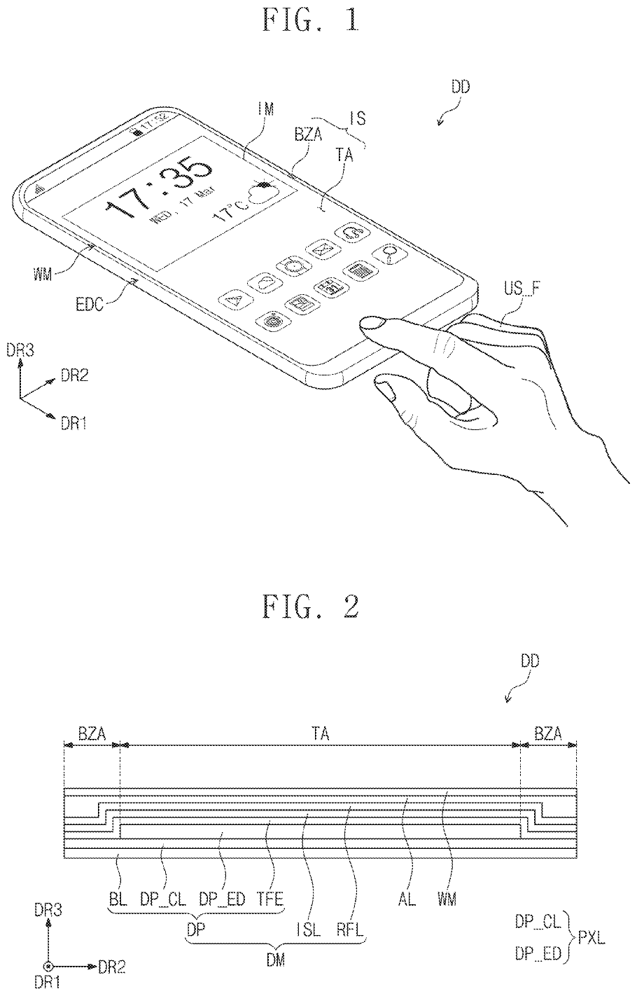

FIG. 1 illustrates a perspective view of a display device DD according to an embodiment of the inventive concept. FIG. 2 illustrates a cross-sectional view of a display device DD according to an embodiment of the inventive concept.

Referring to FIGS. 1 and 2, a display device DD may be a device activated according to electrical signals. For example, the display device DD may be a mobile phone, a tablet, a car navigation system, a game console, or a wearable device, but is not limited thereto. In FIG. 1, as an example, a mobile phone is presented as the display device DD.

An upper surface of the display device DD may be defined as a display surface IS, and may have a plane defined by a first direction DR1 and a second direction DR2. Images IM generated in the display device DD may be provided to users through the display surface IS. Hereinafter, a normal direction substantially perpendicular to a plane defined by the first direction DR1 and the second direction DR2 is defined as a third direction DR3. In the present description, “when viewed on a plane” may be defined as viewed from the third direction DR3. That is, the plane may be parallel to a plane defined by the first direction DR1 and the second direction DR2.

The display surface IS may be divided into a transmission region TA and a bezel region BZA. The transmission region TA may be a portion in which the images IM are displayed. Users view the images IM through the transmission region TA. In the present embodiment, the transmission region TA is shown to have a substantially rectangular with rounded corners. However, this is presented as an example, and the transmission region TA may have various two-dimensional or three-dimensional shapes without limitation.

The bezel region BZA is adjacent to the transmission region TA. The bezel region BZA may have a predetermined color. The bezel region BZA may surround the transmission region TA. Accordingly, the shape of the transmission region TA may be substantially defined by the bezel region BZA. However, this is merely shown as an example, and the bezel region BZA may be disposed adjacent to fewer sides of the transmission region TA or it may be omitted.

The display device DD may sense external inputs applied from the outside. The external inputs may include various forms of inputs provided from the outside of the display device DD. For example, the external inputs may include an external input such as hovering applied while approaching the display device DD or adjacent thereto by a predetermined distance, as well as by direct contact, with a user's hand US_F or the like. In addition, the external inputs may have various forms such as force, pressure, temperature, light, heat, capacitance, inductance, impedance, or the like. The external inputs may be provided through the user's hand, eyes or the like, or through a separate device such as an active pen or a digitizer pen.

The display device DD may detect users' biometric information, such as a fingerprint or an iris scan, applied from the outside. A biometric information sensing region capable of detecting users' biometric information may be provided on the display surface IS of the display device DD. The biometric information sensing region may be provided throughout the transmission region TA or may be provided in a portion of the transmission region TA. FIG. 1 shows that the entire portion of the transmission region TA is used as a biometric information sensing region, but embodiments of the inventive concept are not limited thereto, and the biometric information sensing region may be provided in a portion of the transmission region TA.

An outer portion of the display device DD may include a window WM and a housing EDC. For example, the window WM and the housing EDC may be combined together, and other components of the display device DD, such as a display module DM, may be accommodated therein.

A front surface of the window WM may define the display surface IS of the display device DD. The window WM may include an optically transparent insulating material. For example, the window WM may include glass or plastic. The window WM may have a multi-layer structure or a single-layer structure. For example, the window WM may include a plurality of plastic films bonded through an adhesive, or a glass substrate and a plastic film, which are bonded through an adhesive.

The housing EDC may include a material having a relatively higher rigidity. For example, the housing EDC may include a plurality of frames and/or plates formed of glass, plastic, or metal, or a combination thereof. The housing EDC may stably protect components of the display device DD, which are accommodated in the internal space, against external impacts. A battery module supplying power for the overall operation of the display device DD may be further disposed between the display module DM and the housing EDC.

The display module DM may include a display panel DP, an input sensing layer ISL, and an anti-reflection layer RFL.

The display panel DP may be configured to substantially generate images. The display panel DP may be a light-emitting display panel, and for example, the display panel DP may be an organic light-emitting display panel, an inorganic light-emitting display panel, an organic-inorganic light-emitting display panel, a quantum dot display panel, a micro light-emitting diode (LED) display panel, or a nano LED display panel. Hereinafter, the display panel DP will be described by way of example as an organic light-emitting display panel, without limitation thereto.

The display panel DP includes a base layer BL, a pixel layer PXL, and an encapsulation layer TFE. The display panel DP according to an embodiment of the inventive concept may be a flexible display panel. However, embodiments of the inventive concept are not limited thereto. For example, the display panel DP may be a foldable display panel or a rigid display panel that is folded with respect to a folding axis.

The base layer BL may include a synthetic resin layer. The synthetic resin layer may be a polyimide resin layer, and the material is not particularly limited thereto. In addition, the base layer BL may include a glass substrate, a metal substrate, or an organic/inorganic composite material substrate.

The pixel layer PXL is disposed on the base layer BL. The pixel layer PXL may include a circuit layer DP_CL and an element layer DP_ED. The circuit layer DP_CL is disposed between the base layer BL and the element layer DP_ED.

The circuit layer DP_CL includes at least one insulating layer and a circuit element. Hereinafter, an insulating layer included in the circuit layer DP_CL is referred to as an intermediate insulating layer. The intermediate insulating layer may include at least one intermediate inorganic film and/or at least one intermediate organic film. The circuit element may include a pixel driving circuit included in each of a plurality of pixels for displaying images, a sensor driving circuit included in each of a plurality of sensors for recognizing external information, and the like. The external information may be biometric information. As a non-limiting example, the sensor may be a fingerprint recognition sensor, a proximity sensor, an iris recognition sensor, or the like. In addition, the sensor may be an optical sensor that recognizes biometric information in an optical manner. The circuit layer DP_CL may further include signal lines connected to the pixel driving circuit and/or the sensor driving circuit.

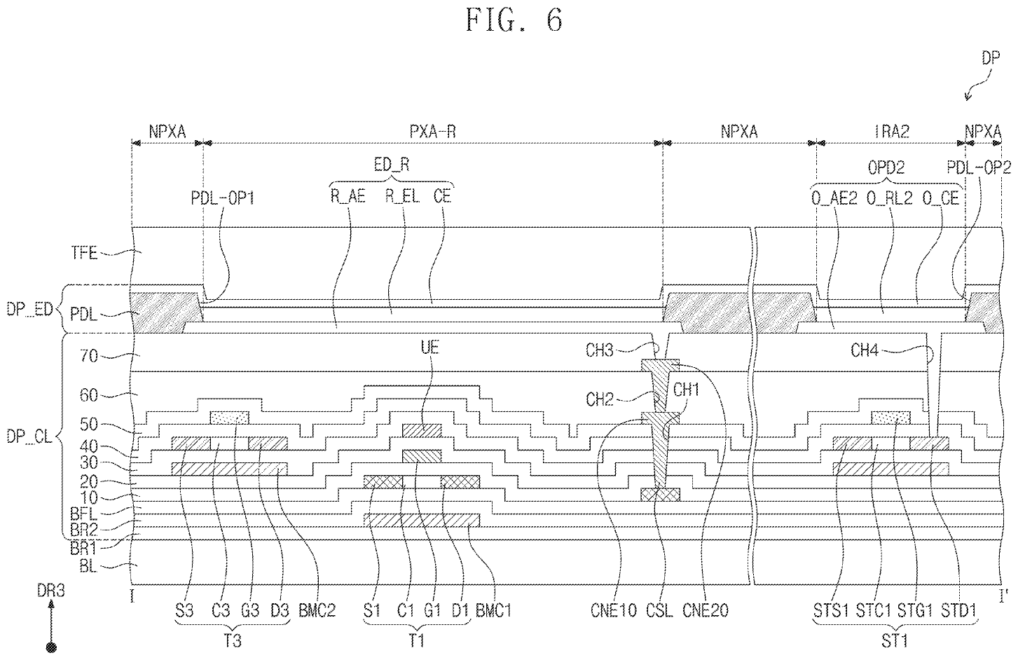

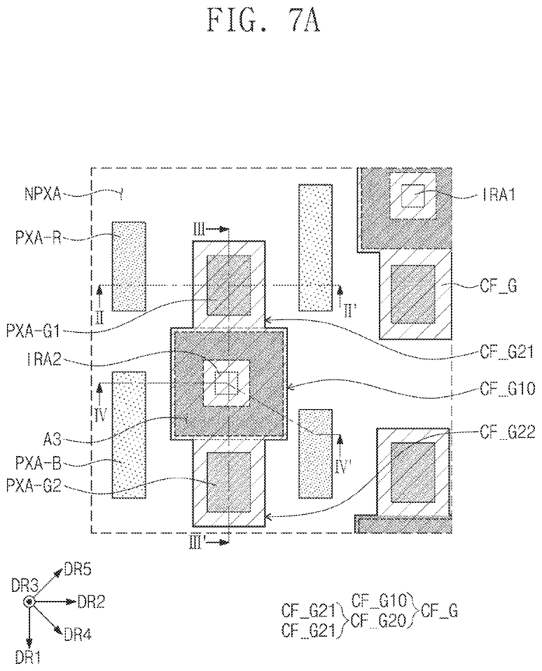

The element layer DP_ED may include a light-emitting element included in each of pixels and a light-receiving element included in each of sensors. As a non-limiting example, the light-receiving element may be a photo-diode. The light-receiving element may be a sensor that detects or responds to light reflected by a user's fingerprint. The circuit layer DP_CL and the element layer DP_ED may be described in greater detail, infra, with reference to FIG. 6.

The encapsulation layer TFE seals the element layer DP-ED. The encapsulation layer TFE may include at least one organic layer and at least one inorganic layer such as an inorganic film. The inorganic film may include an inorganic material, and may protect the element layer DP-ED from moisture/oxygen. The inorganic film may include a silicon nitride layer, a silicon oxy nitride layer, a silicon oxide layer, a titanium oxide layer, an aluminum oxide layer, and the like, but is not particularly limited thereto. The organic layer includes an organic material, and may protect the element layer DP-ED from foreign materials such as dust particles.

The input sensing layer ISL may be formed on the display panel DP. The input sensing layer ISL may be disposed directly on the encapsulation layer TFE. According to an embodiment of the inventive concept, the input sensing layer ISP may be formed on the display panel DP through a roll-to-roll process, without limitation thereto. That is, when the input sensing layer ISL is disposed directly on the display panel DP, an adhesive film need not be disposed between the input sensing layer ISL and the encapsulation layer TFE.

Alternatively, an adhesive film may be disposed between the input sensing layer ISL and the display panel DP. In this case, the input sensing layer ISP need not be manufactured along with the display panel DP through a roll-to-roll process, and after being manufactured through a separate process from the display panel DP, the input sensing unit ISP may be fixed on an upper surface of the display panel DP through an adhesive film.

The input sensing layer ISL may detect external inputs (e.g., a user's touch) to convert the inputs into predetermined types of input signals, and provide the input signals to the display panel DP. The input sensing layer ISL may include a plurality of sensing electrodes for detecting external inputs. The sensing electrodes may sense the external input in a capacitive manner, without limitation thereto. The display panel DP may receive the input signals from the input sensing layer ISL, and may generate images corresponding to the input signals.

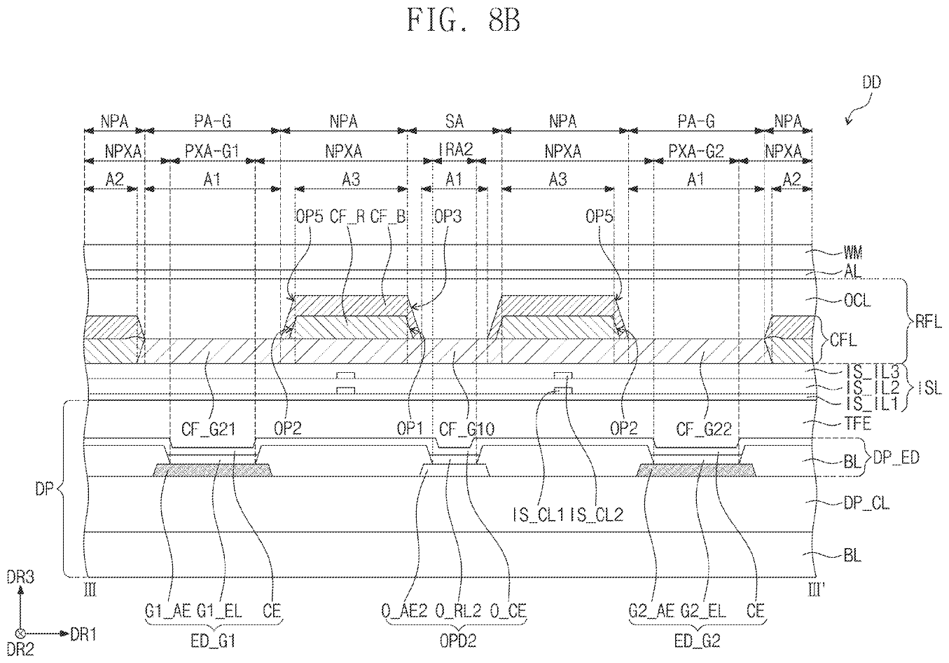

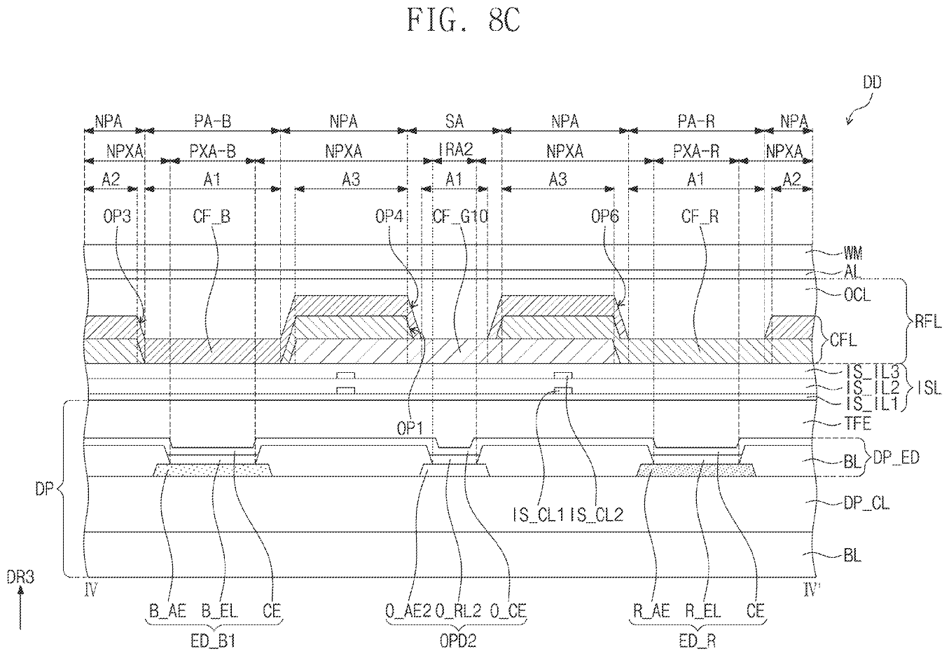

The anti-reflection layer RFL may be disposed on the input sensing layer ISL. The anti-reflection layer RFL may reduce reflectance of external light incident from the outside of the display device DD. The anti-reflection layer RFL may be formed on the input sensing layer ISL through a roll-to-roll process, but embodiments of the inventive concept are not limited thereto. Alternatively, the anti-reflection layer RFL may be disposed between the display panel DP and the input sensing layer ISL. Moreover, a plurality of anti-reflection layers may be disposed above and/or below the input sensing layer. The anti-reflection layer RFL may include a color filter layer CFL (see FIG. 8A), and the color filter layer CFL (see FIG. 8A) may include color filters. Further detailed descriptions of the color filters may be provided, infra. In an alternate embodiment, at least one of the color filter layers may be disposed above the input sensing layer, and at least another of the color filters may be disposed below the input sensing layer.

The display device DD according to an embodiment of the inventive concept may further include an adhesive layer AL. The window WM may be attached to the anti-reflection layer RFL through the adhesive layer AL. The adhesive layer AL may include an optical clear adhesive, an optically clear adhesive resin, or a pressure sensitive adhesive (PSA), without limitation thereto.

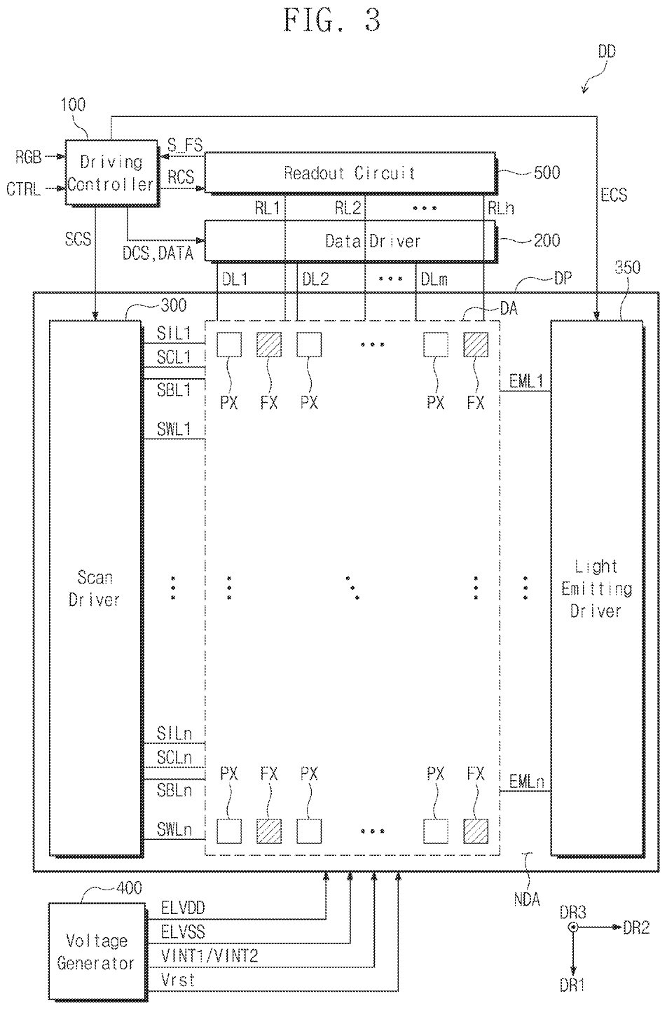

FIG. 3 illustrates a display device DD according to an embodiment of the inventive concept.

Referring to FIG. 3, the display device DD includes a display panel DP, a panel driver, and a driving controller 100. As a non-limiting example, the panel driver includes a data driver 200, a scan driver 300, a light-emitting driver 350, a voltage generator 400, and a readout circuit 500, without limitation thereto.

In operation, the driving controller 100 receives an image signal RGB and a control signal CTRL. The driving controller 100 generates an image data signal DATA in which the data format of the image signal RGB is converted to match the data driver 200 in an interface specification. The driving controller 100 outputs a first control signal SCS, a second control signal ECS, a third control signal DCS, and a fourth control signal RCS.

The data driver 200 receives the third control signal DCS and the image data signal DATA from the driving controller 100. The data driver 200 converts the image data signal DATA into data signals and outputs the data signals to a plurality of data lines DL1 to DLm which may be described in greater detail, infra. The data signals may be analog voltages corresponding to the grayscale values of the image data signal DATA.

The scan driver 300 receives the first control signal SCS from the driving controller 100. The scan driver 300 may output scan signals to scan lines of the display panel DP in response to the first control signal SCS.

The voltage generator 400 generates voltages required for the operation of the display panel DP. In the present embodiment, the voltage generator 400 generates a first driving voltage ELVDD, a second driving voltage ELVSS, a first initialization voltage VINT1, a second initialization voltage VINT2, and a reset voltage Vrst, without limitation thereto.

The display panel DP may include a display region DA corresponding to the transmission region TA (see FIG. 1) and a non-display region NDA corresponding to the bezel region BZA (see FIG. 1). The display panel DP may include a plurality of pixels PX disposed in the display region DA and a plurality of sensors FX disposed in the display region DA.

The display panel DP further includes initialization scan lines SIL1-SILn, compensation scan lines SCL1-SCLn, write scan lines SWL1-SWLn, black scan lines SBL1-SBLn, light-emitting control lines EML1-EMLn, data lines DL1-DLm, and readout lines RL1-RLh.

The initialization scan lines SIL1-SILn, the compensation scan lines SCL1-SCLn, the write scan lines SWL1-SWLn, the black scan lines SBL1-SBLn, and the light-emitting control lines EML1-EMLn extend in the second direction DR2. The initialization scan lines SIL1-SILn, the compensation scan lines SCL1-SCLn, the write scan lines SWL1-SWLn, the black scan lines SBL1-SBLn, and the light-emitting control lines EML1-EMLn are arranged to be spaced apart in the first direction DR1. The data lines DL1-DLm and the readout lines RL1-RLh extend in the first direction DR1 and are arranged to be spaced apart in the second direction DR2. In an alternate embodiment, the scan driver 300 and the light-emitting driver 350 need not be on opposite sides of the display region DA.

The plurality of pixels PX are each electrically connected to the initialization scan lines SIL1-SILn, the compensation scan lines SCL1-SCLn, the write scan lines SWL1-SWLn, the black scan lines SBL1-SBLn, the light-emitting control lines EML1-EMLn, and the data lines DL1-DLm. For example, each of the plurality of pixels PX may be electrically connected to four scan lines. However, the number of scan lines connected to respective pixels PX is not limited thereto and may change.

The plurality of sensors FX are each electrically connected to the write scan lines SWL1-SWLn and the readout lines RL1-RLh. One sensor FX may be electrically connected to one scan line. However, embodiments of the inventive concept are not limited thereto. The number of scan lines connected to each sensor FX may vary. As a non-limiting example, the number of the readout lines RL1-RLh may correspond to half the number of the data lines DL1-DLm. However, embodiments of the inventive concept are not limited thereto. Alternatively, the number of the readout lines RL1-RLh may correspond to one-fourth or one-eighth of the number of the data lines DL1-DLm. In other embodiments, the number of the readout lines RL1-RLh may substantially equal or be correspondingly greater than the number of data lines DL1-DLm.

The scan driver 300 may be disposed in the non-display region NDA of the display panel DP. However, embodiments of the inventive concept are not particularly limited thereto. For example, at least a portion of the scan driver 300 may be disposed in the display region DA.

The scan driver 300 receives the first control signal SCS from the driving controller 100. In response to the first control signal SCS, the scan driver 300 outputs initialization scan signals to the initialization scan lines SIL1-SILn and outputs compensation scan signals to the compensation scan lines SCL1-SCLn. In addition, in response to the first control signal SCS, the scan driver 300 outputs write scan signals to the write scan lines SWL1-SWLn and outputs black scan signals to the black scan lines SBL1-SBLn. Alternatively, the scan driver 300 may include first and second scan drivers. The first scan driver may output initialization scan signals and compensation scan signals, and the second scan driver may output write scan signals and black scan signals, without limitation thereto.

The light-emitting driver 350 may be disposed in the non-display region NDA of the display panel DP. The light-emitting driver 350 receives the second control signal SCS from the driving controller 100. The light-emitting driver 350 may output light-emitting control signals to the light-emitting control lines EML1-EMLn in response to the second control signal ECS. Alternatively, the scan driver 300 may be connected to the light-emitting control lines EML1-EMLn. In this case, the light-emitting driver 350 may be omitted, and the scan driver 300 may output light-emitting control signals to the light-emitting control lines EML1-EMLn.

The readout circuit 500 receives the fourth control signal RCS from the driving controller 100. The readout circuit 500 may receive sensing signals from the readout lines RL1-RLh in response to the fourth control signal RCS. The readout circuit 500 may process detection signals received from the readout lines RL1-RLh and provide the processed detection signals S_FS to the driving controller 100. The driving controller 100 may recognize biometric information based on the detection signals S_FS.

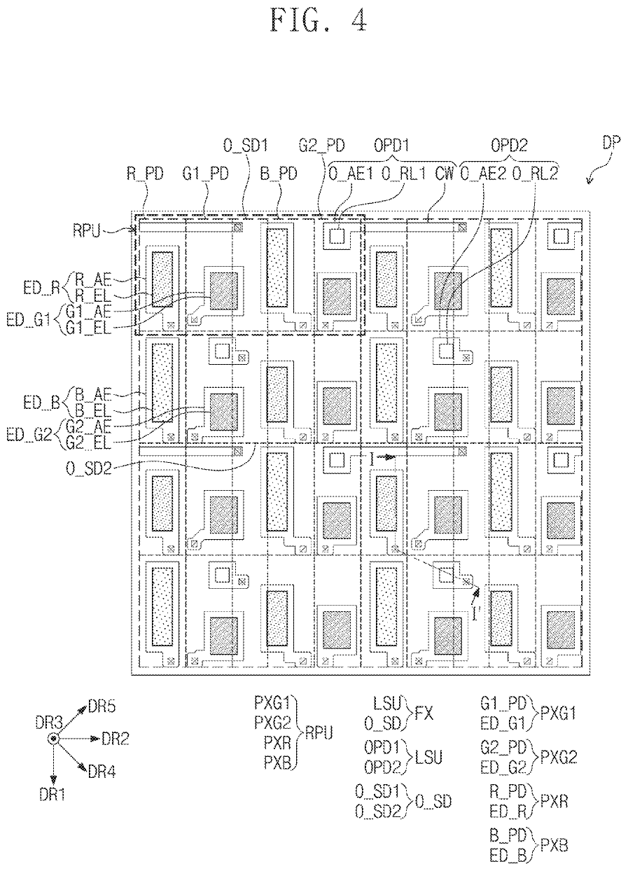

FIG. 4 illustrates a plan view enlarging a portion of a display panel DP according to embodiments of the inventive concept. FIG. 4 shows a connection relationship between a light-emitting element and a pixel driving circuit, and a connection relationship between a light-receiving element and a sensor driving circuit.

Referring to FIG. 4, the display panel DP includes a plurality of pixels PXR, PXG1, PXG2, and PXB and a plurality of sensors FX.

In FIG. 4, unit regions RPUs repeated in the display region DA are separately shown. A unit pixel and at least one sensor FX are disposed in each of the unit regions RPU. The unit pixel may be defined as a group of repeating pixels among the plurality of pixels PX shown in FIG. 3. In the present embodiment, one sensor FX may be disposed in each of the unit regions RPU.

The unit pixel may include two first color pixels PXG1 and PXG2 (hereinafter referred to as a 1-1 color pixel PXG1 and a 1-2 color pixel PXG2), a second color pixel PXR, and a third color pixel PXB. The 1-1 and 1-2 color pixels PXG1 and PXG2 each include first light-emitting elements ED_G1 and ED_G2 (hereinafter, 1-1 light-emitting element ED_G1 and 1-2 light-emitting element ED_G2), the second color pixel PXR includes the second light-emitting element ED_R, and the third color pixel PXB includes the third light-emitting element ED_B.

Each of the 1-1 and 1-2 light-emitting elements ED_G1 and ED_G2 emits first color light (e.g., green light), the second light-emitting element ED_R emits second color light (e.g., red light) different from the first color light, and the third light-emitting element ED_B emits third color light (e.g., blue light) different from the first light and the second color light. The green light emitted from the 1-1 light-emitting element ED_G1 may have substantially the same wavelength as the green light emitted from the 1-2 light-emitting element ED_G2. In alternate embodiments, the wavelengths of light from the light-emitting elements 1-1 and 1-2 may differ, such as to support tetrachromacy, or to further differentiate specular from diffuse reflections of light.

The second light-emitting elements ED_R and the third light-emitting elements ED_B may be alternately arranged in each of the first and second directions DR1 and DR2. The 1-1 and 1-2 light-emitting elements ED_G1 and ED_G2 may be alternately arranged in each of the first and second directions DR1 and DR2. Each of the 1-1 and 1-2 light-emitting elements ED_G1 and ED_G2 may be disposed between the second and third light-emitting elements ED_R and ED_B spaced apart in the second direction DR2.

The unit regions RPUs arranged along the second direction DR2 may have substantially the same pixel arrangement, and in the unit regions RPUs arranged along the first direction DR1, positions of the second color pixel PXR and the third color pixel PXB may be different, and positions of the 1-1 color pixel PXG1 and the 1-2 color pixel PXG2 may be different. Among the unit regions RPU, first type unit regions and second type unit regions may be alternately disposed along the first direction DR1. In an alternate embodiment, the unit regions of the second type and the unit regions of the first type may be substantially similar to mirror images of each other in the second direction. In an alternate embodiment, substantially same unit regions of a single type may have different offsets in the first direction versus the second direction.

The second light-emitting element ED_R, the 1-1 light-emitting element ED-G1, the third light-emitting element ED_B, and the 1-2 light-emitting element ED_G2 may be sequentially arranged in the direction DR2 in each of the first type unit regions. The third light-emitting element ED_B, the 1-2 light-emitting element ED_G2, the second light-emitting element ED_R, and the 1-2 light-emitting element ED_G1 may be sequentially arranged in the direction DR2 in each of the second type unit regions.

The 1-1 light-emitting element ED_G1 may include a 1-1 anode G1_AE and a 1-1 emission layer G1_EL, and the 1-2 light-emitting element ED_G2 may include a 1-2 anode G2_AE and a 1-2 emission layer G2_EL. The second light-emitting element ED_R may include a second anode R_AE and a second emission layer R_EL, and the third light-emitting element ED_B may include a third anode B_AE and a third emission layer B_EL.

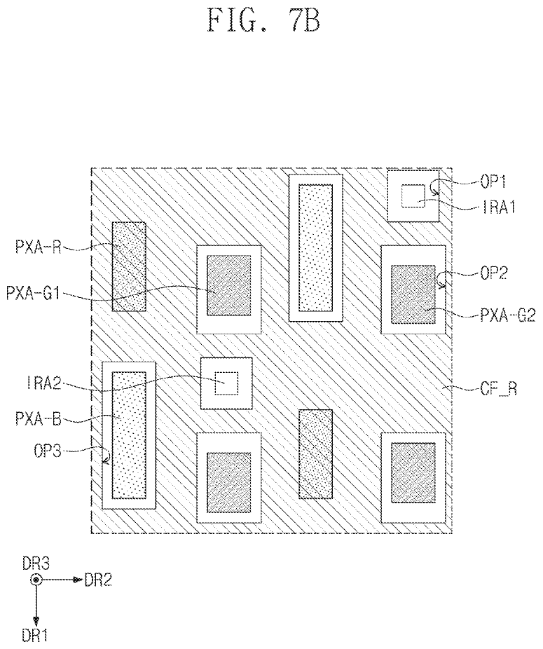

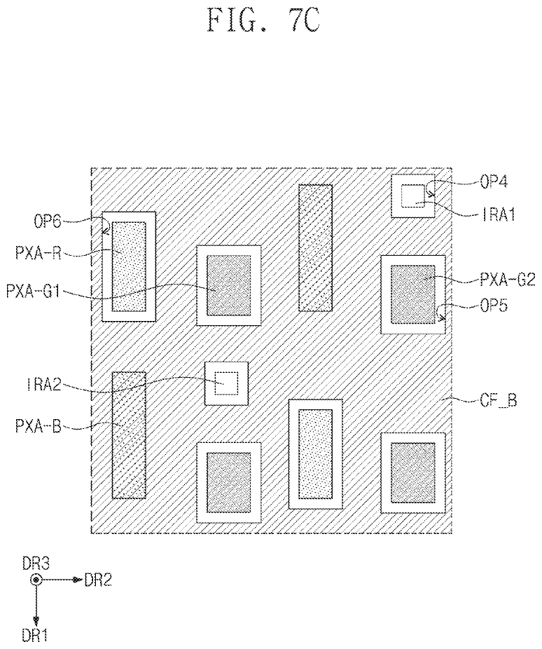

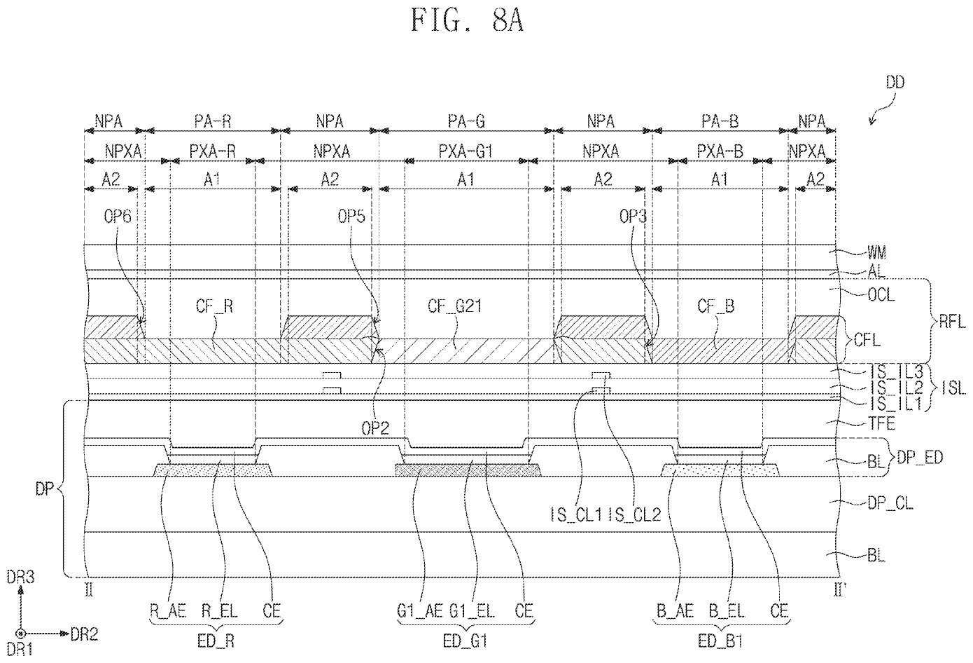

The 1-1 emission layer G1_EL may correspond to a 1-1 color light-emitting region PXA-G1 (or a first sub-light-emitting region) among the first color light-emitting regions PXA-G, which may be described in greater detail, infra, with respect to FIG. 7A, and the 1-2 emission layer G2_EL may correspond to a 1-2 color light-emitting region PXA-G2 among the first color light-emitting regions PXA-G. The second emission layer R_EL may correspond to a second color light-emitting region PXA-R, which may be described in greater detail, infra, with respect to FIG. 7A, and the third emission layer B_EL may correspond to a third color light-emitting region PXA-B, which may also be described in greater detail, infra, with respect to FIG. 7A.

Accordingly, the provided descriptions of the arrangements of the above-described 1-1, 1-2, second, and third light-emitting elements ED_G1, ED_G2, ED_R, and ED_B may also be applied to the 1-1, 1-2, second, and third light-emitting regions PXA-G1, PXA-G2, PXA-R, and PXA-B. In addition, sizes of the 1-1, 1-2, second, and third emission layers G1_EL, G2_EL, R_EL, and B_EL may correspond to sizes of 1-1, 1-2, second, and third light-emitting regions PXA-G1, PXA-G2, PXA-R, and PXA-B, respectively.

As a non-limiting example, the second color light-emitting region PXA-R may be larger in size than the 1-1 and 1-2 color light-emitting regions PXA-G1 and PXA-G2. In addition, the third color light-emitting region PXA-B may be larger in size than the second color light-emitting region PXA-R. The size of each of the first to third color light-emitting regions PXA-G, PXA-R, and PXA-B is not limited thereto and may be modified and applied in various ways. For example, in another embodiment of the inventive concept, the second and third color light-emitting regions PXA-R and PXA-B may be substantially the same in size and may be larger than the first color light-emitting regions PXA-G. Alternatively, the first to third color light-emitting regions PXA-G, PXA-R, and PXA-B may be substantially the same in size.

In the unit region RPU, one of each of a 1-1 pixel driving circuit G1_PD of the 1-1 color pixel PXG1, a 1-2 pixel driving circuit G2_PD of the 1-2 color pixel PXG2, a second pixel driving circuit R_PD of the second color pixel PXR, and a third pixel driving circuit B_PD of the third color pixel PXB are disposed.

The 1-1 light-emitting element ED_G1 is electrically connected to the 1-1 pixel driving circuit G1_PD. The 1-1 anode G1_AE is connected to the 1-1 pixel driving circuit G1_PD through a contact hole. The 1-2 light-emitting element ED_G2 is electrically connected to the 1-2 pixel driving circuit G2_PD. The 1-2 anode G2_AE is connected to the 1-2 pixel driving circuit G2_PD through a contact hole. The second light-emitting element ED_R is electrically connected to the second pixel driving circuit R_PD. The second anode R_AE is connected to the second pixel driving circuit R_PD through a contact hole. The third light-emitting element ED_B is electrically connected to the third pixel driving circuit B_PD. The third anode B_AE is connected to the third pixel driving circuit B_PD through a contact hole.

Each of the sensors FX includes a light-sensing unit LSU and a sensor driving circuit O_SD. The light-sensing unit LSU may include one light-receiving element. As a non-limiting example, one light-receiving element may be disposed to correspond to one unit region RPU. However, the light-sensing unit LSU may include two or more light-receiving elements, and any one of the light-receiving elements may be connected to a sensor driving circuit. In this case, the number of light-receiving elements disposed corresponding to one unit region PRU may be two or more.

In the present embodiment, the light-receiving element may include a first light-receiving element OPD1 and a second light-receiving element OPD2. Each of the first type unit regions may include one first light-receiving element OPD1, and each of the second type unit regions may include one second light-receiving element OPD2. In a corresponding unit region among the unit regions RPU, each of the first and second light-receiving elements OPD1 and OPD2 may be spaced apart from the 1-2 light-emitting element ED_G2 in the first direction DR1 and may be spaced apart from the third light-emitting element ED_B in the direction DR2. The first and second light-receiving elements OPD1 and OPD2 may be substantially similar to mirror images of each other in the first direction DR1.

Each of the first and second light-receiving elements OPD1 and OPD2 may be disposed between the 1-1 and 1-2 light-emitting elements ED_G1 and ED_G2 spaced apart in the first direction DR1. Each of the first and second light-receiving elements OPD1 and OPD2 may be disposed between the second light-emitting elements ED_R spaced apart in a fourth direction DR4 defined as an oblique direction to the first and second directions DR1 and DR2, and may be disposed between third light-emitting elements ED_B spaced apart in a fifth direction DR5 defined as a direction crossing the fourth direction DR4. The first light-receiving elements OPD1 may be arranged in the second direction DR2, and the second light-receiving elements OPD2 may be arranged in the second direction DR2. The first and second light-receiving elements OPD1 and OPD2 may be arranged in the fourth and fifth directions DR4 and DR5, respectively.

The first light-receiving element OPD1 may include a 4-1 anode O_AE1 and a first photoelectric conversion layer O_RL1, and the second light-receiving element OPD2 may include a 4-2 anode O_AE2 and a second photoelectric conversion layer O_RL2.

The sensor driving circuit O_SD may include a first sensor driving circuit O_SD1 and a second sensor driving circuit O_SD2. The first sensor driving circuit O_SD1 may be disposed in each of the first type unit regions, and the second sensor driving circuit O_SD2 may be disposed in each of the second type unit regions. The first and second sensor driving circuits O_SD1 and O_SD2 may be alternatingly arranged in the first direction DR1, the plurality of first sensor driving circuits O_SD1 may be consecutively arranged in the second direction DR2, and the plurality of second sensor driving circuits O_SD2 may be consecutively arranged in the second direction DR2.

The first light-receiving element OPD1 is electrically connected to the first sensor driving circuit O_SD1. The 4-1 anode O_AE1 is connected to the first sensor driving circuit O_SD1 through a contact hole. The second light-receiving element OPD2 is electrically connected to the second sensor driving circuit O_SD2. The 4-2 anode O_AE2 is connected to the second sensor driving circuit O_SD2 through a contact hole.

In an embodiment, the first light-receiving element OPD1 may further include an extension wire CW extending from the 4-1 anode O_AE1 in the second direction DR2. The 4-1 anode O_AE1 and the extension wire CW may be in the form of a single body. The 4-1 anode O_AE1 may be connected to the first sensor driving circuit O_SD1 through a contact hole defined at an end portion of the extension wire CW. The contact hole of the extension wire CW and the contact hole of the 4-2 anode O_AE2 may be spaced apart in at least one of the first direction DR1 or the second direction DR2.

The 4-1 anode O_AE1, the 4-2 anode O_AE2, and the extension wire CW are disposed on the same layer as the 1-1, 1-2, second, and third anodes G1_AE, G2_AE, R_AE, and B_AE, respectively. In this case, the 4-1 anode O_AE1, the 4-2 anode O_AE2, and the extension wire CW may include substantially the same material as the 1-1, 1-2, second, and third anodes G1_AE, G2_AE, R_AE, and B_AE, respectively, and may be provided through substantially the same process.

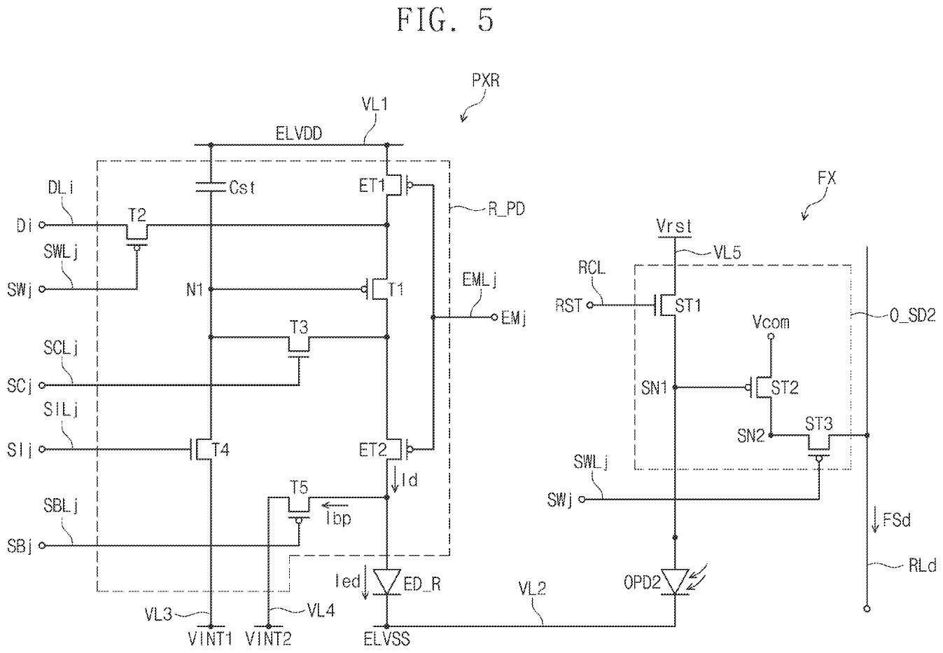

FIG. 5 illustrates a circuit for a pixel PXR and a sensor FX according to an embodiment of the inventive concept.

FIG. 5 shows the circuit for one pixel (e.g., the second color pixel PXR) among the plurality of pixels PX shown in FIG. 3 as an illustrative example, without limitation thereto. Since each of the plurality of pixels PX (see FIG. 3) may share substantially the same circuit structure, detailed descriptions of the other pixels may be omitted. In addition, in FIG. 5, a circuit for one sensor (e.g., the sensor FX including the second light-receiving element OPD2 and the second sensor driving circuit O_SD2) among the plurality of sensors FX shown in FIG. 3 is shown as an example. Since each of the plurality of sensors FX may share substantially the same circuit structure, detailed descriptions of the other sensors may be omitted.

Referring to FIGS. 3 and 5, the second color pixel PXR is connected to an i-th data line DLi among the data lines DL1-DLm, a j-th initialization scan line SILj among the initialization scan lines SIL1-SILn, a j-th compensation scan line SCLj among the compensation scan lines SCL1-SCLn, a j-th write scan line SWLj among the write scan lines SWL1-SWLn, a j-th black scan line SBLj among the black scan lines SBL1-SBLn, and a j-th light-emitting control line EMLj among the light-emitting control lines EML1-EMLn.

The second color pixel PXR includes the second light-emitting element ED_R and the second pixel driving circuit R_PD. The second light-emitting element ED_R may be a light-emitting diode. As a non-limiting example, the second light-emitting element ED_R may be an organic light-emitting diode including an organic emission layer.

The second pixel driving circuit R_PD includes first to fifth transistors T1, T2, T3, T4, and T5, first and second light-emitting control transistors ET1 and ET2, and one capacitor Cst.

At least one of the first to fifth transistors T1, T2, T3, T4, and T5 and/or the first and second light-emitting control transistors ET1 and ET2 may be a transistor having a low-temperature polycrystalline silicon (LTPS) semiconductor layer. At least one of the first to fifth transistors T1, T2, T3, T4, and T5 and/or the first and second light-emitting control transistors ET1 and ET2 may be a transistor having an oxide semiconductor layer. For example, the third and fourth transistors T3 and T4 may be oxide semiconductor transistors, and the first, second, and fifth transistors T1, T2, and T5 and the first and second light-emitting control transistors ET1 and ET2 may be LTPS transistors.

In this embodiment, at least the first transistor T1 that directly affects the brightness of the display device DD (see FIG. 1) is configured to include a semiconductor layer formed of polycrystalline silicon having high reliability, and accordingly, a high resolution display device may be obtained. For the transistors having an oxide semiconductor layer, the oxide semiconductor has high carrier mobility and low leakage current, and accordingly does not have a large voltage drop even with long driving time. That is, the color change of images according to the voltage drop is not drastic even upon low-frequency driving, and thus low-frequency driving is supported. As described above, the oxide semiconductor has low leakage current, and thus at least one of the third transistor T3 or the fourth transistor T4 connected to the driving gate electrode of the first transistor T1 may be employed as an oxide semiconductor to reduce or prevent leakage current that might flow to the driving gate electrode, and to reduce power consumption.

Some of the first to fifth transistors T1, T2, T3, T4, and T5 and the first and second light-emitting control transistors ET1 and ET2 may be P-type transistors, and the others may be N-type transistors. For example, the first transistor T1, the second transistor T2, and the fifth transistor T5, and the first and second light-emitting control transistors ET1 and ET2 may be P-type transistors, and the third and fourth transistors T3 and T4 may be N-type transistors.

The configuration of the second pixel driving circuit R_PD according to an embodiment of the inventive concept is not limited to the illustrative embodiment shown in FIG. 5. The second pixel driving circuit R_PD shown in FIG. 5 is merely an example, and the configuration of the second pixel driving circuit R_PD may be modified to address design criteria. For example, the first to fifth transistors T1, T2, T3, T4, and T5 and the first and second light-emitting control transistors ET1 and ET2 may be of the same type, that is either P-type transistors or N-type transistors.

The j-th initialization scan line SILj, the j-th compensation scan line SCLj, the j-th write scan line SWLj, the j-th black scan line SBLj, and the j-th light-emitting control line EMLj may transmit the j-th initialization scan signal Slj, the j-th compensation scan signal SCj, the j-th write scan signal SWj, the j-th black scan signal SBj, and the j-th light-emitting control signal EMj, respectively, to the second color pixel PXR. The i-th data line DLi transmits the i-th data signal Di to the second color pixel PXR. The i-th data signal Di may have a voltage level corresponding to the image signal RGB input to the display device DD (see FIG. 3), for example.

The first and second driving voltage lines VL1 and VL2 may transmit the first driving voltage ELVDD and the second driving voltage ELVSS, respectively, to the second color pixel PXR. In addition, the first and second initialization voltage lines VL3 and VL4 may transmit the first initialization voltage VINT1 and the second initialization voltage VINT2, respectively, to the second color pixel PXR.

The first transistor T1 is connected between the first driving voltage line VL1 receiving the first driving voltage ELVDD and the second light-emitting element ED_R. The first transistor T1 may include a first electrode connected to the first driving voltage line VL1 via the first light-emitting control transistor ET1, a second electrode connected to a second anode R_AE (see FIG. 4) of the second light-emitting element ED_R via the second light-emitting control transistor ET2, and a third electrode (e.g., a gate electrode) connected to one end (e.g., a first node N1) of the capacitor Cst. The first transistor T1 may receive the i-th data signal Di received from the i-th data line DLi according to the switching operation of the second transistor T2, and supply a driving current Id to the second light-emitting element ED_R.

The second transistor T2 is connected between the data line DLi and the first electrode of the first transistor T1. The second transistor T2 includes a first electrode connected to the data line DLi, a second electrode connected to the first electrode of the first transistor T1, and a third electrode (e.g., a gate electrode) connected to the j-th write scan line SWLj. The second transistor T2 may be turned on according to the write scan signal SWj received through the j-th write scan line SWLj to transmit the i-th data signal Di received through the i-th data line DLi to the first electrode of the first transistor T1.

The third transistor T3 is connected between the second electrode of the first transistor T1 and the first node N1. The third transistor T3 includes a first electrode connected to the third electrode of the first transistor T1, a second electrode connected to the second electrode of the first transistor T1, and a third electrode (e.g., a gate electrode) connected to the j-th compensation scan line SCLj. The third transistor T3 may be turned on according to the j-th compensation scan signal SCj received through the j-th compensation scan line SCLj to connect the third electrode and the second electrode of the first transistor T1, thereby configuring the first transistor T1 as a diode-connected transistor.

The fourth transistor T4 is connected between the first initialization voltage line VL3 to which the first initialization voltage VINT1 is applied and the first node N1. The fourth transistor T4 includes a first electrode connected to the first initialization voltage line VL3 to which the first initialization voltage VINT1 is applied, a second electrode connected to the first node N1, and a third electrode (e.g., a gate electrode) connected to the j-th initialization scan line SILj. The fourth transistor T4 is turned on according to the j-th initialization scan signal Slj received through the j-th initialization scan line SILj. The turned-on fourth transistor T4 delivers the first initialization voltage VINT1 to the first node N1 to initialize the potential of the third or gate electrode (i.e., the potential of the first node N1) of the first transistor T1.

The first light-emitting control transistor ET1 includes a first electrode connected to the first driving voltage line VL1, a second electrode connected to the first electrode of the first transistor T1, and a third electrode (e.g., a gate electrode) connected to the j-th light-emitting control line EMLj.

The second light-emitting control transistor ET2 includes a first electrode connected to the second electrode of the first transistor T1, a second electrode connected to a second anode R_AE (see FIG. 4) of the second light-emitting element ED_R, and a third electrode (e.g., a gate electrode) connected to the j-th light-emitting control line EMLj.

The first and second light-emitting control transistors ET1 and ET2 are turned on together according to the j-th light-emitting control signal EMj received through the j-th light-emitting control line EMLj. The first driving voltage ELVDD applied through the turned-on first light-emitting control transistor ET1 may be compensated through the diode-connected first transistor T1 and then delivered to the second light-emitting element ED_R.

The fifth transistor T5 includes a first electrode connected to the second initialization voltage line VL4 to which the second initialization voltage VINT2 is delivered, a second electrode connected to the second electrode of the second light-emitting control transistor ET2, and a third electrode (e.g., a gate electrode) connected to the j-th black scan line SBLj. The second initialization voltage VINT2 may have a voltage level equal to or lower than the first initialization voltage VINT1. As a non-limiting example, each of the first and second initialization voltages VINT1 and VINT2 may have a voltage of about −3.5 V.

As described above, one end of the capacitor Cst is connected to the third electrode of the first transistor T1, and the other end thereof is connected to the first driving voltage line VL1. A cathode of the second light-emitting element ED_R may be connected to the second driving voltage line VL2 that delivers the second driving voltage ELVSS. The second driving voltage ELVSS may have a lower voltage level than the first driving voltage ELVDD. As a non-limiting example, the first driving voltage ELVDD may be about 4.6 V, and the second driving voltage ELVSS may be about −2.5 V.

The sensor FX is connected to a d-th readout line RLd among the readout lines RL1-RLh, the j-th write scan line SWLj, and a reset control line RCL.

The sensor FX includes the light-sensing unit LSU and the sensor driving circuit O_SD. In the present embodiment, the light-sensing unit LSU may include a corresponding light-receiving element among the first and second light-receiving elements OPD1 and OPD2. However, embodiments of the inventive concept are not limited thereto, and the light-sensing unit LSU may include one or more light-receiving elements connected in series, or two or more light-receiving elements connected in parallel. Hereinafter, a detailed description of the substantially similar first light-receiving element OPD1 may be omitted.

The second light-receiving element OPD2 may be a photodiode. As a non-limiting example, the second light-receiving element OPD2 may be an organic photo-diode including an organic material as a photoelectric conversion layer. The 4-2 anode O_AE2 of the second 4-2 light-receiving element OPD2 may be connected to a first sensing node SN1, and the cathode of the second light-receiving element OPD2 may be connected to the second driving voltage line VL2 having the second driving voltage ELVSS.

The second sensor driving circuit O_SD2 includes three transistors ST1, ST2, and ST3. The three transistors ST1, ST2, and ST3 may include a reset transistor ST1, an amplification transistor ST2, and an output transistor ST3, respectively. At least one of the reset transistor ST1, the amplification transistor ST2, or the output transistor ST3 may be an oxide semiconductor transistor. As a non-limiting example, the reset transistor ST1 may be an oxide semiconductor transistor, and the amplification transistor ST2 and the output transistor ST3 may be LTPS transistors. However, embodiments are not limited thereto, and at least the reset transistor ST1 and the output transistor ST3 may be oxide semiconductor transistors, and the amplification transistor ST2 may be an LTPS transistor.

In addition, some of the reset transistor ST1, the amplification transistor ST2, and the output transistor ST3 may be P-type transistors, and some may be N-type transistors. As a non-limiting example, the amplification transistor ST2 and the output transistor ST3 may be P-type transistors, and the reset transistor ST1 may be an N-type transistor. However, the present invention is not limited thereto, and the reset transistor ST1, the amplification transistor ST2, and the output transistor ST3 may be of the same type, that is either N-type transistors or P-type transistors.

The circuit configuration of the second sensor driving circuit O_SD2 according to an embodiment of the inventive concept is not limited to what is shown in FIG. 5. The second sensor driving circuit O_SD2 shown in FIG. 5 is merely an example, and the configuration of the second sensor driving circuit O_SD2 may be modified to address design criteria.

The reset transistor ST1 includes a first electrode connected to the third initialization voltage line VL5 to receive a reset voltage Vrst, a second electrode connected to the first sensing node SN1, and a third electrode (e.g., a gate electrode) to receive a reset control signal RST. The reset transistor ST1 may reset the potential of the first sensing node SN1 to the reset voltage Vrst in response to the reset control signal RST. The reset control signal RST may be a signal provided through the reset control line RCL. However, embodiments of the inventive concept are not limited thereto. Alternatively, the reset control signal RST may be the j-th compensation scan signal SCj supplied through the j-th compensation scan line SCLj. That is, the reset transistor ST1 may receive the j-th compensation scan signal SCj supplied from the j-th compensation scan line SCLj as the reset control signal RST. As a non-limiting example, the reset voltage Vrst may have a lower voltage level than the second driving voltage ELVSS at least over an active duration of the reset control signal RST. The reset voltage Vrst may be a DC voltage kept at a voltage level lower than the second driving voltage ELVSS. For example, the reset voltage Vrst may be about −4.5 V.

The amplification transistor ST2 includes a first electrode receiving a sensing driving voltage Vcom, a second electrode connected to the second sensing node SN2, and a third electrode (e.g., a gate electrode) connected to the first sensing node SN1. The amplification transistor ST2 may be turned on according to the potential of the first sensing node SN1 to apply the sensing driving voltage Vcom to the second sensing node SN2. As a non-limiting example, the sensing driving voltage Vcom may be one of the first driving voltage ELVDD, the first initialization voltage VINT1, or the second initialization voltage VINT2. When the sensing driving voltage Vcom is the first driving voltage ELVDD, the first electrode of the amplification transistor ST2 may be electrically connected to the first driving voltage line VL1. When the sensing driving voltage Vcom is the first initialization voltage VINT1, the first electrode of the amplification transistor ST2 may be electrically connected to the first initialization voltage line VL3, and when the sensing driving voltage Vcom is the second initialization voltage VINT2, the first electrode of the amplification transistor ST2 may be electrically connected to the second initialization voltage line VL4.

The output transistor ST3 includes a first electrode connected to the second sensing node SN2, a second electrode connected to the d-th readout line RLd, and a third electrode (e.g., a gate electrode) receiving an output control signal. The output transistor ST3 may deliver a sensing signal FSd to the d-th readout line RLd in response to the output control signal. The output control signal may be the j-th write scan signal SWj supplied through the j-th write scan line SWLj. That is, the output transistor ST3 may receive the j-th write scan signal SWj supplied from the write scan line SWLj as an output control signal.

The light-sensing unit LSU of the sensor FX may be exposed to light during a light-emitting period of light-emitting elements ED_G1, ED_G2, ED_R, and ED_B. The light may be light output from any one of the light-emitting elements ED_G1, ED_G2, ED_R, and ED_B.

When a user's hand US_F (see FIG. 1) touches the display surface IS (see FIG. 1), the second light-receiving element OPD2 may generate photo-charges corresponding to light reflected by ridges of the fingerprint or valleys between the ridges of the fingerprint, and the generated photo-charges may be accumulated in the first sensing node SN1.

The amplification transistor ST2 may be a source-follower amplifier that generates a source-drain current in proportion to an electric charge of the first sensing node SN1 input to the third electrode.

A low level j-th write scan signal SWj is supplied to the output transistor ST3 through the j-th write scan line SWLj. When the output transistor ST3 is turned on in response to the low level j-th write scan signal SWj, the sensing signal FSd corresponding to the current flowing through the amplification transistor ST2 may be output to the d-th readout line RLd.

When a high level reset control signal RST is supplied through the reset control line RCL, the reset transistor ST1 is turned on. The reset period may be defined as an active duration (i.e., a high level duration) of the reset control line RCL. Alternatively, when the reset transistor ST1 is formed of a PMOS transistor instead of an NMOS transistor, a low level reset control signal RST may be supplied to the reset control line RCL over the reset duration. Over the reset duration, the first sensing node SN1 may be reset to a potential corresponding to the reset voltage Vrst. As a non-limiting example, the reset voltage Vrst may have a lower voltage level than the second driving voltage ELVSS.

When the reset duration ends, the light-sensing unit LSU may generate photo-charges corresponding to received light, and the generated photo-charges may be accumulated in the first sensing node SN1.

FIG. 6 illustrates a cross-sectional view of a display panel DP according to an embodiment of the inventive concept. For example, a cross-section shown in FIG. 6 may correspond to the cross-section taken along line I-I′ shown in FIG. 4.

Referring to FIGS. 4 and 6, the display panel DP may include a base layer BL, a circuit layer DP_CL disposed on the base layer BL, an element layer DP_ED disposed on the circuit layer DP_CL, and an encapsulation layer TFE disposed on the element layer DP_ED.

The base layer BL may include a synthetic resin layer. The synthetic resin layer may include a thermosetting resin. In particular, the synthetic resin layer may be a polyimide-based resin layer, and the material is not particularly limited thereto. The synthetic resin layer may include at least any one among an acrylic-based resin, a methacrylate-based resin, polyisoprene, a vinyl-based resin, an epoxy-based resin, a urethane-based resin, a cellulose-based resin, a siloxane-based resin, a polyamide-based resin, a perylene-based resin, or the like. In addition, the base layer may include a glass substrate, a metal substrate, or an organic/inorganic composite material substrate.

At least one inorganic layer is formed on an upper surface of the base layer BL. The inorganic layer may include at least one among aluminum oxide, titanium oxide, silicon oxide, silicon oxynitride, zirconium oxide, and/or hafnium oxide. The inorganic layer may be formed as multiple layers. The multi-layered inorganic layers may constitute barrier layers BR1 and BR2 and/or a buffer layer BFL, which may be described in greater detail, infra. The barrier layers BR1 and BR2 and the buffer layer BFL may be selectively disposed.

The barrier layers BR1 and BR2 may prevent foreign substances from being introduced from the outside. The barrier layers BR1 and BR2 may include a silicon oxide layer and a silicon nitride layer. Each of these may be provided in plurality, and silicon oxide layers and silicon nitride layers may be alternately stacked.

The barrier layers BR1 and BR2 may include a first barrier layer BR1 and a second barrier layer BR2. A first rear metal layer BMC1 may be disposed between the first barrier layer BR1 and the second barrier layer BR2. In an embodiment of the inventive concept, the first rear metal layer BMC1 may be omitted.

The buffer layer BFL may be disposed on the barrier layers BR1 and BR2. The buffer layer BFL may increase the bonding force between the base layer BL and semiconductor patterns and/or conductive patterns. The buffer layer BFL may include a silicon oxide layer and a silicon nitride layer. Silicon oxide layers and silicon nitride layers may be alternately stacked.

A first semiconductor pattern may be disposed on the buffer layer BFL. The first semiconductor pattern may include a silicon semiconductor. For example, the silicon semiconductor may include amorphous silicon, polycrystalline silicon, or the like. For example, the first semiconductor pattern may include low-temperature polysilicon.

FIG. 6 shows a portion of the first semiconductor pattern disposed on the buffer layer BFL, and the first semiconductor pattern may be further disposed in another region. The first semiconductor pattern may be arranged by specific rules over pixels. The first semiconductor pattern may have different electrical properties according to provisioning with and/or without doping. The first semiconductor pattern may include a first region having high conductivity and a second region having low conductivity. The first region may be doped with an N-type dopant or a P-type dopant. A P-type transistor may include a doped region doped with the P-type dopant, and an N-type transistor may include a doped region doped with the N-type dopant. The second region may be a non-doped region or may be doped in a lower concentration than the first region.

The first region has greater conductivity than the second region, and may substantially serve as an electrode or a signal line. The second region may substantially correspond to an active region (or a channel) of the transistor. That is, a portion of the semiconductor pattern may be an active region of the transistor, another portion may be a source or drain of the transistor, and the other portion may be a connection electrode or a connection signal line.

A first electrode S1, a channel portion C1, and a second electrode D1 of a first transistor T1 are formed from the first semiconductor pattern. The first electrode S1 and the second electrode D1 of the first transistor T1 extend in opposite directions from the channel portion C1.

A portion of a connection signal line CSL formed from the first semiconductor pattern is illustrated in FIG. 6. The connection signal line CSL may be connected to the second electrode of the fifth transistor T5 of FIG. 5 when viewed on a plane.

A first insulating layer 10 may be disposed on the buffer layer BFL. A first insulating layer 10 may commonly overlap a plurality of pixels and cover the first semiconductor pattern. The first insulating layer 10 may be an inorganic layer and/or an organic layer, and have a single-layered or multi-layered structure. The first insulating layer 10 may include at least one among aluminum oxide, titanium oxide, silicon oxide, silicon nitride, silicon oxynitride, zirconium oxide, and hafnium oxide. In the present embodiment, the first insulating layer 10 may be a single-layered silicon oxide layer, without limitation thereto. Insulating layers of the circuit layer DP_CL, which may be described in greater detail, infra, in addition to the first insulating layer 10, may be inorganic layers and/or organic layers, and have single-layer or multi-layer structures. The inorganic layer may include at least one of the materials described above, but is not limited thereto.

A third electrode G1 of the first transistor T1 of FIG. 5 is disposed on the first insulating layer 10. The third electrode G1 may be a portion of a metal pattern. The third electrode G1 of the first transistor T1 overlaps the channel portion C1 of the first transistor T1. In the process of doping the first semiconductor pattern, the third electrode G1 of the first transistor T1 may serve as a mask. The third electrode G1 may include titanium (Ti), silver (Ag), silver-containing alloy, molybdenum (Mo), molybdenum-containing alloy, aluminum (Al), aluminum-containing alloy, aluminum nitride (AlN), tungsten (W), tungsten nitride (WN), copper (Cu), indium tin oxide (ITO), indium zinc oxide (IZO), and the like, but is not particularly limited thereto.

A second insulating layer 20 may be disposed on the first insulating layer 10 and may cover the third electrode G1 of the first transistor T1. The second insulating layer 20 may be an inorganic layer and/or an organic layer, and may have a single-layered or multi-layered structure. The second insulating layer 20 may include at least one of silicon oxide, silicon nitride, or silicon oxynitride. In the present embodiment, the second insulating layer 20 may have a multi-layered structure including a silicon oxide layer and a silicon nitride layer.

An upper electrode UE and a second rear metal layer BMC2 may be disposed on the second insulating layer 20. The upper electrode UE may overlap the third electrode G1. The upper electrode UE may be a portion of a metal pattern. A portion of the third electrode G1 of the first transistor T1 and the upper electrode UE overlapping the portion may define the capacitor Cst (see FIG. 5). In an embodiment of the inventive concept, the second insulating layer 20 may be replaced with an insulating pattern. In this case, the upper electrode UE may be disposed on the insulating pattern, and the upper electrode UE may serve as a mask for forming an insulating pattern from the second insulating layer 20.

The second rear metal layer BMC2 may be disposed to correspond to a lower portion of an oxide thin film transistor, for example, a third transistor T3 of FIG. 5. The second rear metal layer BMC2 may receive a constant voltage or a signal.

A third insulating layer 30 may be disposed on the second insulating layer and may cover the upper electrode UE and the second rear metal layer BMC2. In an alternate embodiment, the second rear metal layer BMC2 may be substituted or omitted. The third insulating layer 30 may have a single-layered or multi-layered structure. For example, the third insulating layer 30 may have a multi-layered structure including a silicon oxide layer and a silicon nitride layer.

A second semiconductor pattern may be disposed on the third insulating layer 30. The second semiconductor pattern may include an oxide semiconductor. The oxide semiconductor may include a plurality of regions divided according to whether metal oxides are reduced. A region in which the metal oxides are reduced (hereinafter, reduction region) has greater conductivity than a region in which the metal oxides are not reduced (hereinafter, non-reduction region). The reduction region substantially serves as a source/drain of transistors or signal lines. The non-reduction region substantially corresponds to an active region (or a semiconductor region, a channel) of transistors. That is, a portion of the second semiconductor pattern may be an active region of a transistor, another portion may be a source/drain region of a transistor, and the other portion may be a signal transmission region.

A first electrode S3, a channel portion C3, and a second electrode D3 of the third transistor T3 are formed from the second semiconductor pattern. The first electrode S3 and the second electrode D3 include a metal reduced from a metal oxide semiconductor. The first electrode S3 and the second electrode D3 may extend in opposite directions from the channel portion C3 on a cross-section.

A fourth insulating layer 40 may be disposed on the third insulating layer 30. A fourth insulating layer 40 may commonly overlap a plurality of pixels and cover the second semiconductor pattern. The fourth insulating layer 40 may include at least one among aluminum oxide, titanium oxide, silicon oxide, silicon nitride, silicon oxynitride, zirconium oxide, and hafnium oxide.

A third electrode G3 of the third transistor T3 is disposed on the fourth insulating layer 40. The third electrode G3 may be a portion of a metal pattern. The third electrode G3 of the third transistor T3 overlaps the channel portion C3 of the third transistor T3. In a process of doping the second semiconductor pattern, the third electrode G3 may serve as a mask. In an embodiment of the inventive concept, the fourth insulating layer 40 may be replaced with an insulating pattern.

A fifth insulating layer 50 may be disposed on the fourth insulating layer 40 and may cover the third electrode G3. The fifth insulating layer 50 may be an inorganic layer.

A first connection electrode CNE10 may be disposed on the fifth insulating layer 50. The first connection electrode CNE10 may be connected to the connection signal line CSL through a contact hole CH1 passing through the first to fifth insulating layers 10, 20, 30, 40, and 50.

A sixth insulating layer 60 may be disposed on the fifth insulating layer 50. The sixth insulating layer 60 may be an organic layer. An organic layer may include general polymers (such as benzocyclobutene (BCB), polyimide, hexamethyldisiloxane (HMDSO), polymethylmethacrylate (PMMA), or polystyrene (PS)), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and/or a blend thereof, but is not particularly limited thereto.

A second connection electrode CNE20 may be disposed on the sixth insulating layer 60. The second connection electrode CNE20 may be connected to the first connection electrode CNE10 through a second contact hole CH2 passing through the sixth insulating layer 60. A seventh insulating layer 70 may be disposed on the sixth insulating layer 60 and may cover the second connection electrode CNE20. The seventh insulating layer 70 may be an organic layer.

A first electrode layer is disposed on the circuit layer DP_CL. The pixel defining film PDL is formed over the first electrode layer. The first electrode layer may include 1-1, 1-2, second, and third anodes G1_AE, G2_AE, R_AE, and B_AE. Each of the 1-1, 1-2, second, and third anodes G1_AE, G2_AE, R_AE, and B_AE may be disposed on the seventh insulating layer 70 and may be connected to the second connection electrode CNE20 through the third contact hole CH3 passing through the seventh insulating layer 70.

First and second film openings PDL-OP1 and PDL-OP2 are provided in the pixel defining film PDL. The first film openings PDL-OP1 expose each of at least a portion of the 1-1 and 1-2 anodes G1_AE and G2_AE, the second anode R_AE, and/or the third anode B_AE. FIG. 6 shows the first film opening PDL-OP1 exposing at least a portion of the second anode R_AE.

In an embodiment, the pixel defining film PDL may further include a black material. The pixel defining film PDL may further include a black organic dye/pigment such as carbon black or aniline black. The pixel defining film PDL may be formed when a blue organic material is mixed with a black organic material. The pixel defining film PDL may further include a liquid-repellent organic material.

As shown in FIG. 6, the display panel DP may include a second color light-emitting region PXA-R and a non-light-emitting region NPXA adjacent to the second color light-emitting region PXA-R. In the present embodiment, the second color light-emitting region PXA-R is defined to correspond to a portion of the second anode R_AE exposed from the pixel defining film PDL by the first film opening PDL-OP1.

The display panel DP may further include first color light-emitting regions (1-1 and 1-2 color light-emitting regions PXA-G1 and PXA-G2) overlapping each of the 1-1 and 1-2 anodes G1_AE and G2_AE, and a third color light-emitting region PXA-B overlapping the third anode B_AE. The non-light-emitting region NPXA may surround each of the 1-1, 1-2, second, and third light-emitting regions PXA-G1, PXA-G2, PXA-R, and PXA-B.

An emission layer may be disposed on the first electrode layer. The emission layer may include 1-1, 1-2, second, and third emission layers G1_EL, G2_EL, R_EL, and B_EL. The 1-1, 1-2, second, and third emission layers G1_EL, G2_EL, R_EL, and B_EL may each be disposed in regions corresponding to the first film openings PDL-OP1. The 1-1, 1-2, second, and third emission layers G1_EL, G2_EL, R_EL, and B_EL may be separately formed in the 1-1, 1-2, second, and third pixels PXG1, PXG2, PXR, and PXB, respectively.

Each of the 1-1, 1-2, second, and third emission layers G1_EL, G2_EL, R_EL, and B_EL may include an organic material and/or an inorganic material. The 1-1, 1-2, second, and third emission layers G1_EL, G2_EL, R_EL, and B_EL may generate light of a predetermined color. For example, each of the 1-1 and 1-2 emission layers G1_EL and G2_EL may generate first color light (green light), the second emission layer R_EL may generate second color light (red light), and the third light emission layer B_EL may generate third color light (blue light), without limitation thereto. In an alternate embodiment, each of the 1-1 and 1-2 emission layers G1_EL and G2_EL may generate different colors of light.

In the present embodiment, patterned 1-1, 1-2, second, and third emission layers G1_EL, G2_EL, R_EL, and B_EL are described as an example, but one emission layer may be commonly disposed in a plurality of light-emitting regions. In this case, the emission layer may generate white light or blue light. In addition, the emission layer may have a multilayer structure referred to as a tandem structure.

Each of the 1-1, 1-2, second, and third emission layers G1_EL, G2_EL, R_EL, and B_EL may include a low molecular weight organic material or a high molecular weight organic material as a light-emitting material. Alternatively, each of the 1-1, 1-2, second, and third emission layers G1_EL, G2_EL, R_EL, and B_EL may include a quantum dot material as a light-emitting material. The core of a quantum dot may be selected from a Group II-VI compound, a Group III-V compound, a Group IV-VI compound, a Group IV element, a Group IV compound, and/or a combination thereof.

A first cathode CE is disposed on the 1-1, 1-2, second, and third emission layers G1_EL, G2_EL, R_EL, and B_EL. As a non-limiting example, the first cathode CE may be commonly disposed in the 1-1, 1-2, second, and third color light-emitting regions PXA-G1, PXA-G2, PXA-R, and PXA-B, and the non-light-emitting region NPXA.

The circuit layer DP_CL may further include the first and second sensor driving circuits O_SD1 and O_SD2 (see FIG. 5). FIG. 6 shows the second sensor driving circuit O_SD2 (see FIG. 5) as an example, without limitation thereto. For convenience of description, the reset transistor ST1 of the second sensor driving circuit O_SD2 (see FIG. 5) is shown. A first electrode STS1, a channel portion STC1, and a second electrode STD1 of a reset transistor ST1 are formed from the second semiconductor pattern. The first electrode STS1 and the second electrode STD1 include a metal reduced from a metal oxide semiconductor. The fourth insulating layer 40 is disposed to cover the first electrode STS1, the channel portion STC1, and the second electrode STD1 of the reset transistor ST1. The third electrode STG1 of the reset transistor ST1 is disposed on the fourth insulating layer 40. In the present embodiment, the third electrode STG1 may be a portion of a metal pattern. The third electrode STG1 of the reset transistor ST1 overlaps the channel portion STC1 of the reset transistor ST1.

As a non-limiting example, the reset transistor ST1 may be disposed on the same layer as the third transistor T3. That is, the first electrode STS1, the channel portion STC1, and the second electrode STD1 of the reset transistor ST1 may be formed through substantially the same process as the first electrode S3, the channel portion C3, and the second electrode D3 of the third transistor T3. The third electrode STG1 of the reset transistor ST1 may be formed along with the third electrode G3 of the third transistor T3 through substantially the same process. Moreover, the first and second electrodes of an amplifying transistor ST2 and an output transistor ST3 of the sensor driving circuit O_SD may be formed through substantially the same process as the first electrode S1 and the second electrode D1 of the first transistor T1. The reset transistor ST1 and the third transistor T3 may be formed on the same layer through substantially the same process, and thus an additional process for forming the reset transistor ST1 may be obviated, thereby increasing process efficiency and/or reducing costs.

The element layer DP_ED may further include first and second light-receiving elements OPD1 and OPD2 (see FIG. 5). FIG. 6 shows the second light-receiving element OPD2 as an example, and substantially duplicate description for the first light-receiving element OPD1 may be omitted.

The second light-receiving element OPD2 may include a 4-2 anode O_AE2, a second photoelectric conversion layer O_RL2, and a second cathode O_CE. The 4-2 anode O_AE2 may be disposed on the same layer as the first electrode layer. That is, the 4-2 anode O_AE2 may be disposed on the circuit layer DP_CL and may be formed along with the 1-1, 1-2, second, and third anodes G1_AE, G2_AE, R_AE, and B_AE through the same process. The 4-2 anode O_AE2 may be connected to the second electrode STD1 of the reset transistor ST1 through a fourth contact hole CH4 formed through the seventh, sixth, fifth and fourth insulating layers 70, 60, 50 and 40, and the 4-2 anode O_AE2 may thus be electrically connected to the reset transistor ST1.

The second film opening PDL-OP2 of the pixel defining film PDL exposes at least a portion of the 4-2 anode O_AE2. The display panel DP further includes light-receiving regions (a first light-receiving region IRA1 (see FIG. 7A) and a second light-receiving region IRA2), and the second light-receiving region IRA2 is defined to correspond to a portion of the 4-2 anode O_AE2 exposed from the pixel defining film PDL by the second film opening PDL-OP2. The non-light-emitting region NPXA may surround each of the first and second light-receiving regions IRA1 and IRA2.

A second photoelectric conversion layer O_RL2 is disposed on the 4-2 anode O_AE2 exposed by the second film opening PDL-OP2. The second photoelectric conversion layer O_RL2 may include an organic photo-sensing material. The second cathode O_CE may be disposed on the second photoelectric conversion layer O_RL2. The second cathode O_CE may be formed along with the first cathode CE through substantially the same process. As a non-limiting example, the second cathode O_CE may be in the form of a single body with the first cathode CE.

Each of the 4-2 anode O_AE2 and the second cathode O_CE may receive electrical signals. The 4-2 anode O_AE2 may receive signals different from those of the second cathode O_CE. Accordingly, a predetermined electric field may be formed between the 4-2 anode O_AE2 and the second cathode O_CE. The second photoelectric conversion layer O_RL2 generates electrical signals corresponding to light incident on a sensor. The second photoelectric conversion layer O_RL2 may absorb energy of incident light to generate charges. For example, the second photoelectric conversion layer O_RL2 may include a light-sensitive semiconductor material.

The charges generated in the second photoelectric conversion layer O_RL2 change the electric field between the 4-2 anode O_AE2 and the second cathode O_CE. The amount of charges generated in the second photoelectric conversion layer O_RL2 may vary depending on whether light is incident on the second light-receiving element OPD2, and the amount and intensity of light incident on the second light-receiving element OPD2. Accordingly, the electric field formed between the 4-2 anode O_AE2 and the second cathode O_CE may vary. The second light-receiving element OPD2 according to an embodiment of the inventive concept may obtain fingerprint information of users through changes in the electric field between the 4-2 anode O_AE2 and the second cathode O_CE.

Although this is presented as an example, embodiments are not limited thereto, and the second light-receiving element OPD2 may include a photo transistor including the second photoelectric conversion layer O_RL2 as an active layer. In this case, the second light-receiving element OPD2 may obtain fingerprint information by sensing the amount of current flowing through the photo transistor. The second light-receiving element OPD2 according to an embodiment of the inventive concept may include various photoelectric conversion elements capable of generating electrical signals in response to changes in the amount of light, and is not limited to any one embodiment.

The encapsulation layer TFE is disposed on the element layer DP-ED. The encapsulation layer TFE includes at least an inorganic layer or an organic layer. In an embodiment of the inventive concept, the encapsulation layer TFE may include two inorganic layers and an organic layer disposed therebetween. In an embodiment of the inventive concept, the encapsulation layer TFE may include a plurality of inorganic layers and a plurality of organic layers, which are alternately stacked.

The inorganic layer of the encapsulation layer TFE may protect the 1-1, 1-2, second, and third light-emitting elements ED_G1, ED_G2, ED_R, and ED_B from moisture/oxygen, and the organic layer of the encapsulation layer TFE may protect the 1-1, 1-2, second, and third light-emitting elements ED_G1, ED_G2, ED_R, and ED_B, and the first and second light-receiving elements OPD1 and OPD2 from foreign substances such as dust particles. The inorganic layer of the encapsulation layer TFE may include a silicon nitride layer, a silicon oxy nitride layer, a silicon oxide layer, a titanium oxide layer, an aluminum oxide layer, and the like, but is not particularly limited thereto. The organic layer of the encapsulation layer TFE may include an acrylic-based organic layer, but is not particularly limited thereto.

FIGS. 7A to 7C are plan views showing some components of a display device according to an embodiment of the inventive concept. FIG. 8A illustrates a cross-sectional view of a display device taken along line II-II′ of FIG. 7A according to an embodiment of the inventive concept. FIG. 8B illustrates a cross-sectional view of a display device taken along line III-Ill′ of FIG. 7A according to an embodiment of the inventive concept. FIG. 8C illustrates a cross-sectional view of a display device taken along line IV-IV′ of FIG. 7A according to an embodiment of the inventive concept.

FIGS. 7A to 7C respectively show first to third color filters CF_G, CF_R, and CF_B constituting a color filter layer CFL in the anti-reflection layer RFL, and describe an arrangement relationship of each the first to third color filters CF_G, CF_R and CF_B with the 1-1, 1-2, second, and third color light-emitting regions PXA-G1, PXA-G2, PXA-R, and PXA-B) and the first and second light-receiving regions IRA1 and IRA2 when viewed on a plane.

FIG. 8A shows a cross-section of the display device DD for one first color light-emitting region (1-1 color light-emitting region PXA-G1), one second color light-emitting region PXA-R, and one third color light-emitting region PXA-B. FIG. 8B shows a cross-section of the display device DD for one light-receiving region (second light-receiving region IRA2) and the 1-1 and 1-2 color light-emitting regions PXA-G1 and PXA-G2 adjacent thereto, and FIG. 8C shows a cross-section of the display device DD for one light-receiving region (second light-receiving region IRA2) and second and third color light-emitting regions PXA-R and PXA-B adjacent thereto.

First, referring to FIG. 8A, the display device DD includes a display panel DP, an input sensing layer ISL disposed on the display panel DP, an anti-reflection layer RFL disposed on the input sensing layer ISL, and a window WM disposed on the anti-reflection layer RFL.

The input sensing layer ISL may be disposed directly on the encapsulation layer TFE, which, in turn, may be disposed directly on the display panel DP. The input sensing layer ISL may detect external inputs applied from the outside. The external inputs may include various forms of inputs provided from the outside of the display device DD.

The input sensing layer ISL may include a lower insulating layer IS_IL1, a first conductive layer IS_CL1, an interlayer insulating layer IS_IL2, a second conductive layer IS_CL2, and an upper insulating layer IS_IL3. In an embodiment of the inventive concept, the lower insulating layer IS_IL1 may be omitted.

Each of the first conductive layer IS_CL1 and the second conductive layer IS_CL2 may have a structure of a single layer or a structure of multiple layers stacked along the third direction DR3. The conductive layer having the multi-layered structure may include at least two or more layers of transparent conductive layers and/or metal layers. The conductive layer having the multi-layered structure may include metal layers having different metals. Each of the transparent conductive layers may include indium tin oxide (ITO), indium zinc oxide (IZO), zinc oxide (ZnO), indium tin zinc oxide (ITZO), PEDOT, a metal nano wire, and/or graphene. Each of the metal layers may include molybdenum, silver, titanium, copper, aluminum, and/or an alloy thereof. For example, each of the first conductive layer IS_CL1 and the second conductive layer IS_CL2 may have a three-layered metal structure, such as, a three-layered structure of titanium/aluminum/titanium. A metal having relatively higher durability and lower reflectivity may be applied to upper/lower layers, and/or a metal having higher electrical conductivity may be applied to an inner layer.

Each of the first conductive layer IS_CL1 and the second conductive layer IS_CL2 includes a plurality of conductive patterns. Hereinafter, the first conductive layer IS_CL1 is described to include first conductive patterns, and the second conductive layer IS-CL2 is described to include second conductive patterns. Each of the first conductive patterns and the second conductive patterns may include sensing electrodes and signal lines connected thereto. The sensing electrodes may be provided in the form of meshes when viewed on a plane. The sensing electrodes may overlap the non-light-emitting region NPXA, and in the sensing electrodes, first to third mesh openings respectively corresponding to the first to third color light-emitting regions PXA-G1, PXA-G2, PXA-R, and PXA-B may be defined, and a fourth mesh opening corresponding to each of the first and second light-receiving regions IRA1 and IRA2 may be defined.

Each of the lower insulating layer IS-IL1, the interlayer insulating layer IS-IL2, and/or the upper insulating layer IS-IL3 may include an inorganic film or an organic film. In the present embodiment, the lower insulating layer IS-IL1 and the interlayer insulating layer IS-IL2 may be inorganic films. In addition, the upper insulating layer IS-IL3 may include an organic film.

The anti-reflection layer RFL may be disposed on the input sensing layer ISL. The anti-reflection layer RFL may be directly disposed on the input sensing layer ISL. In the present embodiment, the anti-reflection layer RFL may include a color filter layer CLF and an overcoating layer OCL. The color filter layer CLF may include first color filters CF_G, second color filters CF_R, and third color filters CF_B. Hereinafter, the first to third color filters CF_G, CF_R, and CF_B may be described in greater detail, infra, with respect to FIGS. 7A to 8C. In an alternate embodiment, the first color filters CF_G may include 1-1 color filters CF G1 and/or 1-2 color filters CF G2.

Referring to FIG. 7A and FIGS. 8A to 8C, each of the first color filters CF_G may overlap one light-receiving region of the light-receiving regions IRA1 and IRA2 and at least one first color light-emitting region of the first color light-emitting regions PXA-G1 and PXA-G2. In an embodiment, each of the first color filters CF_G may overlap corresponding light-receiving regions IRA1 and IRA2 and the 1-1 and 1-2 color light-emitting regions PXA-G1 and PXA-G2 spaced apart in the first direction DR1 with the corresponding light-receiving regions IRA1 and IRA2 therebetween.

Each of the first color filters CF_G may include a first portion CF_G10 defined as a portion overlapping the light-receiving regions IRA1 and IRA2, and at least one second portion CF_G20 defined as a portion overlapping at least one first color light-emitting region PXA-G1 and PXA-G2. In an embodiment, each of the first portion CF_G10 and the second portion CF_G20 may be in the form of a single body.

In an embodiment, a plurality of second portions CF_G20 may include a first sub-portion CF_G21 defined as a region overlapping the 1-1 color light-emitting region PXA-G1 (or the first sub-light-emitting region), and a second sub-portion CF_G22 defined as a region overlapping the 1-2 color light-emitting region PXA-G2 (or the second sub-light-emitting region). In this case, each of the first color filters CF_G may overlap one light-receiving region and two first color light-emitting regions adjacent thereto, and the first color filters CF_G may be arranged along each of the first and fourth directions DR1 and DR4.

The first and second sub-portions CF_G21 and CF_G22 may be spaced apart in the first direction DR1 with the first portion CF_G10 therebetween. In an embodiment, the first sub-portion CF_G21, the first portion CF_G10, and the second sub-portion CF_G22 may be sequentially and consecutively arranged, and the first sub-portion CF_G21 and the second sub-portion CF_G22 may thus be in the form of a single body with the first portion CF_G10.

Accordingly, the first portion CF_G10 of the first color filter CF_G may overlap each of a non-light-emitting region NPXA disposed between the 1-1 color light-emitting region PXA-G1 and the corresponding light-receiving regions IRA1 and IRA2, and a non-light-emitting region NPXA disposed between the 1-2 color light-emitting region PXA-G2 and the corresponding light-receiving regions IRA1 and IRA2.

FIG. 7A shows the shape of the first color filter CF_G when viewed on a plane as an illustrative example, but embodiments of the inventive concept are not limited thereto. The shape of the first color filter CF_G is not limited to any one embodiment as long as the first portion CF_G10 overlaps a portion of the corresponding light-receiving regions IRA1 and IRA1, and the second portion overlaps a portion of the corresponding first color light-emitting regions PXA-G1 and PXA-G2.

As shown in FIG. 8A, the first sub-portion CF_G21 according to an embodiment need not overlap the sensing electrodes of each of first and second conductive layers ISL_CL1 and ISL_CL2. In greater detail, the first sub-portion CF_G21 need not overlap sensing electrodes overlapping non-light-emitting regions NPXA disposed between the 1-1 and second color light-emitting regions PXA-G1 and PXA-R and between the 1-1 and third color light-emitting regions PXA-G1 and PXA-B, among the sensing electrodes. The description of the first sub-portion CF_G21 may be similarly applied to the second sub-portion CF_G22. Substantially duplicate description may be omitted.

The first portion CF_G10 according to an embodiment may overlap a portion of the sensing electrodes of each of the first and second conductive layers ISL_CL1 and ISL_CL2. In greater detail, as shown in FIG. 8B, the first portion CF_G10 may overlap sensing electrodes overlapping non-light-emitting regions NPXA disposed between the 1-1 color light-emitting region PXA-G1 and the light-receiving region IRA2 and between the 1-2 color light-emitting region PXA-G2 and the light-receiving region IRA2.

In addition, as shown in FIGS. 7A, 8B and 8C, the first portion CF_G10 may overlap sensing electrodes overlapping non-light-emitting regions NPXA disposed between the second color light-emitting region PXA-R and the corresponding light-receiving region (the second light-receiving region IRA2) and between the third color light-emitting region PXA-B and the second light-receiving region IRA2. However, embodiments of the inventive concept are not limited thereto, and the first portion CF_G10 may overlap or non-overlap a portion of the sensing electrodes overlapping non-light-emitting regions NPXA disposed between the second color light-emitting region PXA-R and the second light-receiving region IRA2 and between the third color light-emitting region PXA-B and the second light-receiving region IRA2, when an upper surface on which the second color filter CF_R and the third color filter CF_B are disposed is provided.

FIG. 7A shows that a width of the first portion CF_G10 in the second direction DR2 is greater than a width of each of the first and second sub-portions CF_G21 and CF_G22 in the second direction DR2, but embodiments of the inventive concept are not limited thereto. For example, the width of the first portion CF_G10 may be equal to or smaller than the width of each of the first and second sub-portions CF_G21 and CF_G22.

Referring to FIGS. 7B and 8A to 8C together, the second color filter CF_R may overlap each of the second color light-emitting regions PXA-R, and need not overlap each of the first light-emitting regions PXA-G1 and PXA-G2, each of the third light-emitting regions PXA3, and each of the light-receiving regions IRA1 and IRA2. The second color filter CF_R may include first openings OP1 each overlapping the light-receiving regions IRA1 and IRA2, second openings OP2 each overlapping the first color light-emitting regions PXA-G1 and PXA-G2, and third openings OP3 each overlapping the third color light-emitting regions PXA-B. The second color filter CF_R may be disposed in the regions except for the first to third openings OP1, OP2, and OP3, in a region overlapping the non-light-emitting region NPXA of the color filter layer CFL.

An area of each of the first openings OP1 may be larger than an area of a corresponding light-receiving region of the light-receiving regions IRA1 and IRA2. An area of each of the second openings OP2 may be larger than an area of a corresponding first color light-emitting region of the first color light-emitting regions PXA-G1 and PXA-G2. An area of each of the third openings OP3 may be larger than an area of a corresponding third light-emitting region of the third color light-emitting regions PXA-B.

The second color filter CF_R may be configured to be formed after forming the first color filters CF_G. As shown in FIG. 8A, an inner surface defining the second opening OP2 of the second color filter CF_R may cover an outer surface of the first sub-portion CF_G21 of the first color filter CF_G. In this case, the second color filter CF_R may further cover a portion of an upper surface of the first sub-portion CF_G21 due to errors in process.

In addition, FIG. 8A shows that the second color filter CF_R protrudes in the thickness direction from a portion adjacent to the second opening OP2 and thus has a convex upper surface as an example, but the shape of the second color filter CF_R may vary depending on process criteria.

As shown in FIGS. 8B and 8C, the second color filter CF_R may be stacked on the first portion CF_G10 overlapping the non-light-emitting region NPXA disposed between a corresponding light-receiving region (the second light-receiving region IRA2) and the light-emitting regions PXA-G1, PXA-G2, PXA-R, and PXA-B adjacent thereto. That is, a portion adjacent to the first opening OP1 among the second color filters CF_R may be disposed on an upper surface of the first portion CF_G10. The second color filter CF_R may cover an outer surface of the first portion CF_G10 of the first color filter CF_G.

Referring to FIGS. 7C and 8A to 8C together, the third color filter CF_B may overlap each of the third color light-emitting regions PXA-B, and need not overlap each of the first color light-emitting regions PXA-G1 and PXA-G2, each of the second color light-emitting regions PXA-R, and each of the light-receiving regions IRA1 and IRA2. Fourth openings OP4, fifth openings OP5, and sixth openings OP6 may be defined in the third color filter CF_B. The third color filter CF_B may be disposed in the regions except for the fourth to sixth openings OP4, OP5, and OP6, in a region overlapping the non-light-emitting region NPXA of the color filter layer CFL.

The fourth openings OP4 may each overlap the light-receiving regions IRA1 and IRA2, and may each correspond to the first openings OP1 of the second color filter CF_R. An area of each of the fourth openings OP4 may be larger than an area of corresponding light-receiving regions IRA1 and IRA2.

The fifth openings OP5 may each overlap the first color light-emitting regions PXA-G1 and PXA-G2, and may each correspond to the second openings OP2 of the second color filter CF_R. An area of each of the fifth openings OP5 may be larger than an area of corresponding first color light-emitting regions PXA-G1 and PXA-G2.

The sixth openings OP6 may each overlap the second color light-emitting regions PXA-R. An area of each of the sixth openings OP6 may be larger than an area of a corresponding second color light-emitting region PXA-R.

The third color filter CF_B may be configured to be formed after forming the first color filters CF G1 and CF G2 and the second color filter CF_R. As shown in FIG. 8A, the third color filter CF_B may be disposed within the third opening OP3 of the second color filter CF_R to cover an inner surface of the second color filter CF_R defining the third opening OP3.

In an embodiment, as shown in FIG. 8A, in a region overlapping non-light-emitting regions NPXA disposed between the 1-1 and second color light-emitting regions PXA-G1 and PXA-R and between the 1-1 and third color light-emitting regions PXA-G1 and PXA-B, an edge formed by a lower surface and an inner surface of the third color filter CF_B defining the fifth opening OP5 may be aligned with an edge formed by an inner surface and an upper surface of the second color filter CF_R defining the second opening OP2. However, embodiments of the inventive concept are not limited thereto, and the third color filter CF_B may cover a portion of an upper surface of the first sub-portion CF_G21.

As shown in FIGS. 8B and 8C, the third color filter CF_B may cover an inner surface of the second color filter CF_R defining the first opening OP1. However, embodiments of the inventive concept are not limited thereto, and an inner surface of the third color filter CF_B defining the fourth opening OP4 may be aligned with the inner surface of the second color filter CF_R defining the first opening OP1 to form a single slope. Alternatively, the third color filter CF_B may expose a portion of the upper surface of the second color filter CF_R adjacent to the first opening OP1.

In a region overlapping non-light-emitting regions NPXA disposed between the second light-receiving region IRA2 and the 1-1 color light-emitting region PXA-G1 and between the second light-receiving region IRA2 and the 1-2 color light-emitting region PXA-G2, the third color filter CF_B may cover an inner surface of the second color filter CF_R defining the second opening OP2.

According to another embodiment of the inventive concept, the third color filter CF_B may be formed before the second color filter CF_R.

In the present embodiment, the display device DD may include pixel regions PA-G, PA-R and PA-B, effective sensing regions SA, and a peripheral region NPA. The pixel regions PA-G, PA-R and PA-B may each correspond to regions from which light provided from the light-emitting elements ED_G1, ED_G2, ED_R, and ED_B is emitted. The pixel regions PA-G, PA-R and PA-B may include first pixel regions PA-G each corresponding to the first color light-emitting regions PXA-G1 and PXA-G2, a second pixel region PA-R corresponding to the second color light-emitting region PXA-R, and a third pixel region PA-B corresponding to the third color light-emitting region PXA-B. The first to third pixel regions PA-G, PA-R and PA-B may respectively provide first to third colors of light.

The first to third pixel regions PA-G, PA-R and PA-B may be defined by openings of the first to third color filters CF_G, CF_R, and CF_B. That is, the first pixel regions PA-G may be defined by openings in the second color filter CF_R and the third color filter CF_B; the second pixel regions PA-R may be defined by openings in the first color filter CF_G and the third color filter CF_B; and the third pixel regions PA-B may be defined by openings in the first color filter CF_G and the second color filter CF_R. Each of the first to third pixel regions PA-G, PA-R and PA-B may be defined by an edge positioned closest to a light-emitting region corresponding to any of the other color filters except for color filters that transmit corresponding color light among the first to third color filters CF_G, CF_R, and CF_B.

For example, each of the first pixel regions PA-G may be defined by the closer of an inner surface of the second color filter defining the second opening and/or an inner surface of the third color filter defining the fifth opening, which may be aligned with each other. The second pixel region PA-R may be defined by a lower edge contacting the second color filter CF_R out of an inner surface of the third color filter CF_B defining the sixth opening OP6. The third pixel region PA-B may be defined by a lower edge contacting an upper insulating layer IS_IL3 out of an inner surface of the second color filter CF_R defining the third opening OP3.

The effective sensing regions SA may correspond to regions into which light is introduced toward the first and second photoelectric conversion layers O_RL1 and O_RL2 of the light-receiving elements OPD1 and OPD2. The effective sensing regions SA may each correspond to the light-receiving regions IRA1 and IRA2. In the present embodiment, each of the effective sensing regions SA may be defined by an upper edge adjacent to the window WM out of the inner surface of the third color filter CF_B defining the fourth opening OP4. In an alternate embodiment, each of the effective sensing regions SA may be defined by an upper edge adjacent to the window WM out of the inner surface of the second color filter CF_R defining the first opening OP1.

The peripheral region NPA may surround each of the first to third pixel regions PA-G, PA-R and PA-B and the effective sensing regions SA.

According to an embodiment of the inventive concept, the color filter layer CFL may include first to third regions A1, A2, and A3. The first region A1 may be defined as a region in which any one color filter among the first to third color filters CF_G, CF_R, and CF_B is disposed. The second region A2 may be defined as a region in which any two color filters among the first to third color filters CF_G, CF_R, and CF_B are stacked and disposed. The third region A3 may be defined as a region in which the first to third color filters CF_G, CF_R, and CF_B are stacked and disposed. As used herein, the expression “color filters are stacked” may indicate that a lower surface of a color filter disposed in an upper portion is disposed to overlap or cover an upper surface of a color filter disposed in a lower portion.

In an embodiment, a dummy region may be further defined in the color filter layer CFL. The dummy region may be defined between the first and second regions A1 and A2 and/or between the first and third regions A1 and A3. The dummy region may be a region having changes in form or placement of the first to third color filters CF_G, CF_R, and CF_B according to process criteria, conditions and/or process anomalies of each of the first to third color filters CF_G, CF_R, and CF_B. For example, as described above, the third color filter CF_B need not cover the inner surface of the second color filter CF_R, and in this case, the third color filter CF_B need not be disposed in the dummy region.

In the present embodiment, the first regions A1 of the color filter layer CFL may each overlap the first to third color light-emitting regions PXA-G1, PXA-G2, PXA-R, and PXA-B. In addition, as each of the first color filters CF_G overlaps corresponding light-receiving regions IRA1 and IRA2, the color filter layer CFL may further include first regions A1 overlapping the light-receiving regions IRA1 and IRA2. Each of the first regions A1 may also overlap a portion of the non-light-emitting region NPXA adjacent to a corresponding light-emitting region or a corresponding light-receiving region.

According to an embodiment of the inventive concept, the second region A2 of the color filter layer CFL may overlap the non-light-emitting region NPXA. In the present embodiment, the second region A2 may include second and third color filters CF_R and CF_B. For example, in the second region A2, the third color filter CF_B may be stacked on the second color filter CF_R.

The second region A2 may overlap a non-light-emitting region NPXA disposed between adjacent light-emitting regions among the first to third color light-emitting regions PXA-G1, PXA-G2, PXA-R, and PXA-B. As shown in FIG. 8A, the second region A2 may overlap a non-light-emitting region NPXA disposed between the 1-1 and second color emitting regions PXA-G1 and PXA-R and a non-light-emitting region NPXA disposed between the 1-1 and third color light-emitting regions PXA-G1 and PXA-B. In addition, the second region A2 may overlap a non-light-emitting region NPXA disposed between the second and third color light-emitting regions PXA-R and PXA-B.

According to an embodiment of the inventive concept, the third region A3 of the color filter layer CFL may overlap the non-light-emitting region NPXA. In the third region A3, the second and third color filters CF_R and CF_B may be stacked on the first color filter CF_G. For example, in the third region A3, the second color filter CF_R may be stacked on the first color filter CF_G, and the third color filter CF_B may be stacked on the second color filter CF_R. In an alternate embodiment, the third color filter CF_B may be stacked on the first color filter CF_G, and the second color filter CF_R may be stacked on the third color filter CF_B.

The third region A3 may overlap a non-light-emitting region NPXA each disposed between the corresponding light-receiving regions IRA1 and IRA2 and respective 1-1, 1-2, second, and third light-emitting regions PXA-G1, PXA-G2, PXA-R, and PXA-B adjacent thereto. That is, as shown in FIG. 7A, the third region A3 may surround each of the light-receiving regions IRA1 and IRA2 when viewed on a plane.

According to an embodiment of the inventive concept, both the second and third regions A2 and A3 may include the second and third color filters CF_R and CF_B. The second color filter CF_R transmits red light and absorbs light of other wavelengths. For example, the second color filter CF_R may transmit light with a wavelength of 570 nm or more and absorb light of other wavelengths. The third color filter CF_B may transmit blue light and absorb light of other wavelengths. For example, the third color filter CF_B may transmit light with a wavelength of 370 nm to 520 nm and absorb light of other wavelengths. Accordingly, the stacked second and third color filters CF_R and CF_B may absorb light of substantially all pertinent wavelengths, and thus block transmission of external light to the inside.

In addition, each of the second and third color filters CF_R and CF_B may overlap the sensing electrodes of the first and second conductive layers IS_CL1 and IS_CL2. That is, on a cross-section, a width of first mesh openings overlapping the first light-emitting regions PXA-G1 and PXA-G2 may be greater than a width of each of the second and fifth openings OP2 and OP5, a width of a second mesh opening overlapping the second light-emitting region PXA-R may be greater than a width of the sixth opening OP6, and a width of a third mesh opening overlapping the third light-emitting region PXA-B may be greater than a width of the third opening OP3. A width of fourth mesh openings overlapping the light-receiving regions IRA1 and IRA2 may be greater than a width of each of the first and fourth openings OP1 and OP4.

Accordingly, external light is prevented from reaching the sensing electrodes, and reduced light reflected from the sensing electrodes is emitted to the outside and reaches users, thereby preventing the sensing electrodes from being viewed. That is, as the reflectance of external light is reduced, visibility defects of the display device DD may be prevented. In addition, even when reduced light reflected from the sensing electrodes and emitted toward the outside is formed in part, transmission to the outside may be blocked as passing through the second and third color filters CF_R and CF_B in the non-light-emitting region NPXA.

Therefore, according to an embodiment of the inventive concept, even when the anti-reflection layer RFL does not include a separate light blocking pattern including a light blocking material having a property of reflecting or absorbing light, such as a shiny or a black material, respectively, reducing or blocking the inflow of external light and reducing or blocking the reflectance of light may still be achieved with the stacking of the second and third color filters CF_R and CF_B. Accordingly, a mask process for forming a light blocking pattern may be skipped, thereby providing a display device DD obtained through a simplified process and/or reduced costs.

In the present embodiment, the anti-reflection layer RFL does not include a separate light blocking pattern, and accordingly, the color filter layer CFL may entirely contact the upper insulating layer IS_IL3 of the input sensing layer ISL in the non-light-emitting region NPXA adjacent to light-emitting regions and, in a region overlapping the non-light-emitting region adjacent to light-receiving regions. That is, the color filter layer CFL may entirely contact an insulating layer disposed on an uppermost side of the insulating layers disposed on the input sensing layer ISL in the region overlapping the non-light-emitting region NPXA.

In the present embodiment, a color filter layer CFL overlapping a non-light-emitting region NPXA disposed between the corresponding light-receiving regions IRA1 and IRA2 and the first to third color light-emitting regions PXA-G1, PXA-G2, PXA-R and PXA-B adjacent thereto may include the third region A3 and have a first maximum thickness. A color filter layer CFL overlapping a non-light-emitting region NPXA disposed between adjacent light-emitting regions among the first to third color light-emitting regions PXA-G1, PXA-G2, PXA-R, and PXA-B may include the second region A2 and have a second maximum thickness. The first maximum thickness is defined from the first to third color filters CF_G, CF_R, and CF_B stacked in the thickness direction, and may thus be greater than the second maximum thickness defined by the second and third color filters CF_R and CF_B stacked in the thickness direction

In addition, in the present embodiment, a distance from the base layer BL to a lower surface of the third color filter CF_B with respect to the thickness direction in the third region A3 may be greater than a distance from the base layer BL to a lower surface of the third color filler CF_B with respect to the thickness direction in the second region A2.

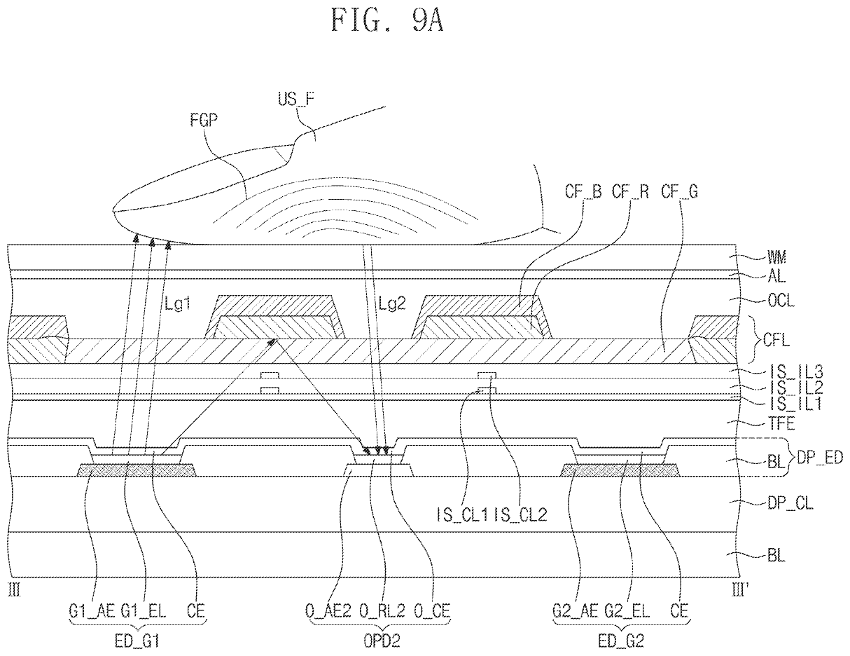

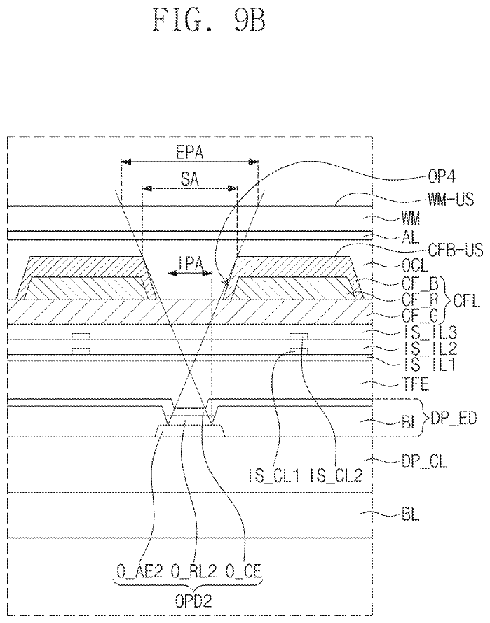

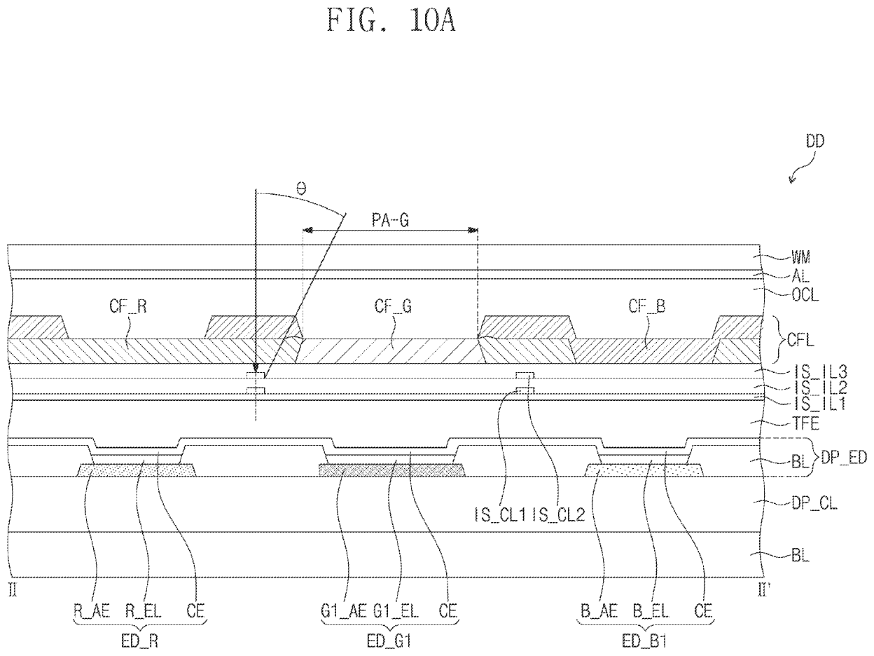

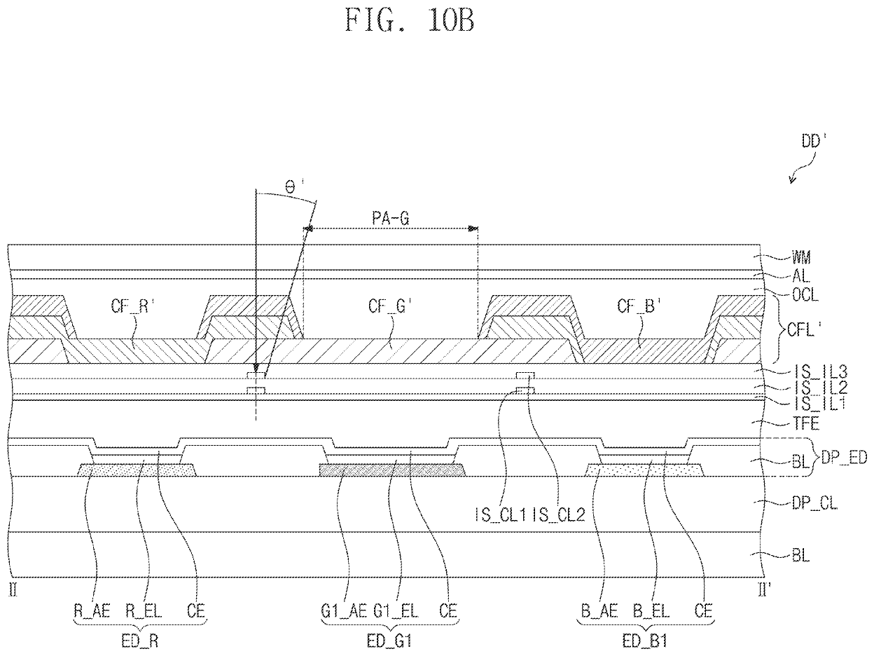

Based on this, according to an embodiment of the inventive concept, in the non-light-emitting region NPXA disposed between the corresponding light-receiving regions IRA1 and IRA2 and the first to third color light-emitting regions PXA-G1, PXA-G2, PXA-R and PXA-B adjacent thereto, the distance between the third color filter CF_B and the window WM may be reduced to increase fingerprint recognition resolution. In the non-light-emitting region NPXA disposed between adjacent light-emitting regions among the first to third color light-emitting regions PXA-G1, PXA-G2, PXA-R, and PXA-B, the distance between the third color filter CF_B and the sensing electrodes may be reduced to reduce defects of visibility from the side. Detailed descriptions thereof may be described in greater detail, infra, with respect to FIGS. 9B to 10B.

FIG. 9A illustrates a cross-sectional view of a display device DD according to an embodiment of the inventive concept. FIG. 8B illustrates a cross-sectional view of a display device DD according to an embodiment of the inventive concept in which a portion of FIG. 9A is enlarged; FIG. 9A shows a cross-section taken along line III-Ill′ shown in FIG. 7A.

Referring to FIG. 9A, when the display device DD runs, each of the first to third light-emitting elements ED_G1, ED_G2, ED_R, and ED_B may emit light. Each of the first light-emitting elements ED_G1 and ED_G2 may emit first color light of a green wavelength band (e.g., green light), the second light-emitting element may emit second color light of a red wavelength band (e.g., red light), and the third light-emitting element may emit third color light of a blue wavelength band (e.g., blue light).

The second light-receiving element OPD2 may receive light of a specific wavelength through the first color filter CF_G disposed on the second light-receiving element OPD2 among the first to third light-emitting elements ED_G1, ED_G2, ED_R, and ED_G. In the present embodiment, the second light-receiving element OPD2 may receive reflected green light Lg2. The reflected green light Lg2 may be defined as light in which green light Lg1 emitted from the first light-emitting elements ED_G1 and ED_G2 is reflected by a user's fingerprint. Red light and blue light emitted from the second and third light-emitting elements ED_R and ED_B may also be reflected by a user's hand US_F, but may be blocked by the first color filter CF_G.

As an illustrative comparison without limitation thereto, in the anti-reflection layer RFL according to an embodiment of the inventive concept, when the color filter layer CFL in which the first to third color filters CF_G, CF_R, and CF_B are stacked is irradiated with light, the amount of light reflected and re-emitted at an interface between the first to third color filters CF_G, CF_R, and CF_B, that is, the reflectance of light at the interface may be 4.32% or less.

When a first Comparative Example 1 including a light blocking pattern having a light blocking material and the first color filter CF_G stacked on the light blocking pattern is irradiated with light, the reflectance of light at the interface may be 4.99%, when a second Comparative Example 2 including a light blocking pattern and the second color filter CF_R stacked on the light blocking pattern is irradiated with light, the reflectance of light at the interface may be 4.63%, and when a third Comparative Example 3 including a light blocking pattern and the third color filter CF_R stacked on the light blocking pattern is irradiated with light, the reflectance of light at the interface may be 4.69%.

That is, the amount of light reflected at the interface between the first to third color filters CF_G, CF_R, and CF_B may be less than the amount of light reflected at the interface between any one of the first to third color filters CF_G, CF_R, and CF_B and the light blocking pattern. Accordingly, the reflectance of external light at the interface within the anti-reflection layer RFL may be reduced to provide a display device DD having optimized visibility.

In addition, when light emitted from an emission layer is reflected at an interface inside the anti-reflection layer RFL, and the light reaches the second photoelectric conversion layer O_RL2, it might thus be provided as noise light to the second photoelectric conversion layer O_RL2. However, according to an embodiment of the inventive concept, the amount of light reflected at the interface inside the anti-reflection layer RFL may be reduced, and accordingly, out of the amount of light incident on the second photoelectric conversion layer O_RL2, the amount of noise light provided by the internal stack structure may be minimized to increase an effective amount of light reflected from a fingerprint. Accordingly, signal-to-noise ratio (SNR) may be optimized. In an alternate embodiment, the amount of noise light incident upon the second photoelectric conversion layer O_RL2 may be further reduced by re-arranging or re-ordering the color filter layers, without limitation.

Referring to FIG. 9B, the fourth opening OP4 of the third color filter CF_B may define an effective sensing region SA. As described above, the effective sensing region SA may be defined by an upper edge of the inner surface of the third color filter CF_B defining the fourth opening OP4.

An effective fingerprint region EPA corresponding to one light-receiving element OPD2 is defined on an upper surface WM-US of the window WM. The effective fingerprint region EPA is defined as a region where effective reflected green light Lg2 (see FIG. 9A) that may pass through the effective sensing region SA and reach the corresponding light-receiving elements OPD1 and OPD2 may be generated or reflected when the user's hand US_F (see FIG. 9A) touches the upper surface WM-US of the window WM. The reflected green light Lg2 (see FIG. 9A) has fingerprint information, such as information about ridges and/or valleys between ridges. The reflected green light Lg2 reflected from the outside of the effective fingerprint region EPA need not pass through the effective sensing region ESA, and accordingly, the corresponding light-receiving elements OPD1 and OPD2 may acquire fingerprint information overlapping the effective sensing region ESA.

When a length of the effective fingerprint region EPA is greater than a reference value, a plurality of ridges or valleys are disposed in the effective fingerprint region EPA, and accurate information about ridges or valleys of the corresponding light-receiving elements OPD1 and OPD2 may be obtained. Information about fingerprint ridges or valleys may be obtained through one effective fingerprint region EPA, and/or using information about a plurality of ridges or valleys acquired through a plurality of valid fingerprint regions EPA, so fingerprint information of a finger contacting the window WM may be completed.

The second and third color filters CF_R and CF_B are disposed on the first color filter CF_G so that the first to third color filters CF_G, CF_R and CF_B are stacked in the thickness direction, and thus a distance between an upper surface CFB-US of the third color filter CF_B disposed on an uppermost side of the color filter layer CFL and the upper surface WM-US of the window WM may be reduced. Accordingly, the length of the effective fingerprint region EPA may be reduced to optimize fingerprint resolution.

The length of the effective fingerprint region EPA may be reduced by reducing the width of openings of the second color filter CF_R and the third color filter CF_B, but if the width of the opening is further decreased, process deviation might reduce yield. According to an embodiment of the inventive concept, without reducing the width of each of the openings of the second and third color filters CF_R and CF_B, high process reliability may be achieved and the length of an effective fingerprint region may be minimized.

FIG. 10A illustrates a cross-sectional view of a display device DD according to an embodiment of the inventive concept. FIG. 10B is a cross-sectional view of a display device DD′ according to a fourth Comparative Example 4.

FIG. 10A shows a cross-section of the display device DD for first to third color light-emitting regions PXA-G1, PXA-G2, PXA-R, and PXA-B (see FIG. 8A) and a non-light-emitting region NPXA (see FIG. 8A) in an embodiment of the inventive concept, and FIG. 10B shows a cross-section of the display device DD′ for first to third color light-emitting regions PPXA-G1, PXA-R, and PXA-B and a non-light-emitting region NPXA in the Comparative Example 4.

Referring to FIGS. 8A, 10A, and 10B, according to the Comparative Example 4, a third region A3 is disposed in a region overlapping non-light-emitting regions NPXA each disposed between the 1-1 and second color light-emitting regions PXA-G1 and PXA-R and between the 1-1 and third color light-emitting regions PXA-G1 and PXA-R. That is, second and third color filters CF_R′ and CF_B′ may be stacked on a first sub-portion CF_G21 of a first color filter CF_G′.

In order for light to be blocked upon passing through the color filter layer CFL, each of the second and third color filters CF_R and CF_B may have a thickness of 1 micrometer or more. That is, the second and third color filters CF_R and CF_B stacked in the thickness direction may be configured to substantially block light (hereinafter, referred to as a ‘light blocking unit’).

In the present embodiment, the stacked second and third color filters CF_R and CF_B are disposed on the upper insulating layer IS_IL3 and are disposed on the same plane as the first color filter CF_G, but in Comparative Embodiment 4, the stacked second and third color filters CF_R′ and CF_B′ are disposed instead on the first color filter CF_G′. That is, in the present embodiment, it is seen that the ‘light-blocking unit’ is disposed on the upper insulating layer IS_IL3, whereas in the Comparative Example 4, the ‘light-blocking unit’ is disposed on the first color filter CF_G′. Accordingly, a distance between the sensing electrodes and the ‘light blocking unit’ in the present embodiment may be closer than that of Comparative Example 4.

In the present embodiment, an area of an opening of the third color filter CF_R corresponding to the 1-1 color light-emitting region PXA-G1 (e.g., PA-G), is substantially equal to an area of an opening of the third color filter CF_R′ corresponding to the 1-1 color light-emitting region PXA-G1 in the Comparative Example 4. With respect to a front view of the display surface IS (see FIG. 1) of the display device DD, when comparing angles at which the sensing electrodes start to be visible as viewed from the side, an angle θ in this embodiment may be greater than an angle θ′ in the Comparative Example 4. Therefore, according to an embodiment of the inventive concept, potential visibility defects, such as if the sensing electrodes were to be viewed from the side, are further minimized, and a display device DD having optimized visibility may thus be provided.

In addition, according to an embodiment of the inventive concept, damage to the color filter layer CFL, such as from a subsequent process, may be prevented by minimizing a portion where a step is formed in the color filter layer CFL. For example, returning to Comparative Example 4, in a region overlapping a non-light-emitting region NPXA adjacent to the third color light-emitting region PXA-B, a first step having a height corresponding to a sum of the height of the first color filter CF_G′ plus the height of the second color filter CF_R′ may be formed in the third color filter layer CF_B′; which is substantially higher than the embodiment of FIG. 10A in which the first step has a height corresponding to the height of the second color filter CF_R′. In addition, in a region overlapping a non-light-emitting region NPXA adjacent to the second color light-emitting region PXA-R, since a portion of the second color filter CF_R′ is already stacked on the first color filter CF_G′, a second step may be formed in a portion covering an outer surface of the first color filter CF_G′.

Accordingly, according to the Comparative Example 4, more and/or high steps may be formed in the second and third color filters CF_R′ and CF_B′, which may, in turn, reduce process reliability of the color filter layer CFL′. In contrast, according to an embodiment of the inventive concept, since relatively small steps are formed in the second and third color filters CF_R and CF_B, process reliability of the color filter layer CFL may be optimized to provide a display device DD having a minimized defect rate.

According to an embodiment of the inventive concept, a display device obtained through simplified processes may be provided by skipping a mask process for separate light blocking patterns. According to an embodiment of the inventive concept, even without separate light blocking patterns, existing light blocking pattern functions may be kept by stacking color filters transmitting different light in multiple layers. This may prevent visibility degradation caused by reflection of external light, even with simplified processes.

According to an embodiment of the inventive concept, out of the amount of light incident on a photoelectric conversion layer, the amount of light from noise light reflected by an internal stack structure may be minimized. That is, out of the amount of light incident on the photoelectric conversion layer, the relative amount of effective light reflected from a fingerprint may increase. Thus, a signal-to-noise ratio may be optimized.

Although the present disclosure has been described with reference to illustrative embodiments of the inventive concept, it shall be understood that the inventive concept should not be limited to these embodiments, but that various changes and modifications can be made by those of ordinary skill in the pertinent art without departing from the spirit and scope of the present disclosure. Accordingly, the technical scope of the inventive concept is not intended to be limited to the contents set forth in the detailed description of the specification, but is intended to be defined by the appended claims.

What is claimed is:

1. A display device comprising:
a base layer, including light-emitting regions of first to third colors, respectively, at least one light-receiving region, and a non-light-emitting region surrounding the light-emitting regions and the at least one light-receiving region;
a display element layer disposed on the base layer, including first to third light-emitting elements each corresponding to the light-emitting regions of the first to third colors, respectively, and a light-receiving element corresponding to the at least one light-receiving region; and
a color filter layer disposed on the display element layer and including first to third color filters,
wherein the color filter layer includes:
first regions each having one color filter corresponding to a respective one of the first to third color filters disposed therein and each overlapping a respective one of the first to third color light-emitting regions;
a second region in which two different color filters of the first to third color filters are stacked; and
a third region in which three different color filters of the first to third color filters are stacked,
wherein the third region surrounds the light-receiving region when viewed on a plane.

2. The display device of claim 1,
wherein in the third region, the second and third color filters are stacked on the first color filter.

3. The display device of claim 1,
wherein in each of the second and third regions, the third color filter is disposed on the second color filter,
wherein in a thickness direction of the base layer, a distance from the base layer to the third color filter in the third region is greater than a distance from the base layer to the third color filter in the second region.

4. The display device of claim 1,
wherein the color filter layer overlapping the non-light-emitting region between the light-receiving region and the light-emitting region adjacent to the light-receiving region among the first to third color light-emitting regions is thicker than the color filter layer overlapping the non-light-emitting region between adjacent light-emitting regions among the first to third color light-emitting regions.

5. The display device of claim 1,
wherein the second region overlaps each of the non-light-emitting region disposed between the first and second light-emitting regions, the non-light-emitting region disposed between the first and third color light-emitting regions, and the non-light-emitting region disposed between the second and third color light-emitting regions.

6. The display device of claim 1,
wherein in the second region, the two color filters among the first to third color filters are the second and third color filters.

7. The display device of claim 1, wherein the first color filter comprises:
a first portion overlapping the light-receiving region; and
a second portion overlapping the first light-emitting region.

8. The display device of claim 7, further comprising:
an input sensing layer including a sensing electrode overlapping the non-light-emitting region and at least one insulating layer covering the sensing electrode, and disposed between the display element layer and the color filter layer,
wherein the sensing electrode overlaps each of the second and third color filters.

9. The display device of claim 8,
wherein the sensing electrode overlapping the non-light-emitting region overlaps the first portion in each space between the light-receiving region and the first color light-emitting region, between the light-receiving region and the second color light-emitting region, and between the light-receiving region and the third color light-emitting region.

10. The display device of claim 8,
wherein the sensing electrode overlapping the non-light-emitting region non-overlaps the second portion in each space between the first and second light-emitting regions, between the first and third light-emitting regions, and between the second and third light-emitting regions.

11. The display device of claim 8,
wherein the color filter layer overlapping the non-light-emitting region is entirely in contact with an insulating layer disposed on an uppermost side of the at least one insulating layer.

12. The display device of claim 7,
wherein each of the first to third color light-emitting regions is in plurality,
wherein the second and third color light-emitting regions are alternately arranged in each of a first direction and a second direction perpendicular to the first direction, and
wherein the first color light-emitting regions comprise a first sub-light-emitting region and a second sub-light-emitting region, the first and second sub-light-emitting regions are alternately arranged in each of the first and second directions, and each of the first and second sub-light-emitting regions is disposed between the second and third color light-emitting regions spaced apart in the second direction.

13. The display device of claim 12,
wherein one first sub-light-emitting region, one second sub-light-emitting region, one second color light-emitting region, and one third color light-emitting region define a unit light-emitting region,
wherein one light-receiving region is disposed within the unit light-emitting region, and
wherein the light-receiving region is disposed between the first and second sub-light-emitting regions spaced apart in the first direction.

14. The display device of claim 13,
wherein the second portion comprises a first sub-portion overlapping the first sub-light-emitting region, and a second sub-portion overlapping the second sub-light-emitting region, which are spaced apart in the first direction with the first portion therebetween, and
wherein the first and second sub-portions are in the form of a single body with the first portion.

15. The display device of claim 1,
wherein in the second color filter, a first opening overlapping the light-receiving region, a second opening overlapping the first color light-emitting region, and a third opening overlapping the third color light-emitting region are defined.

16. The display device of claim 15,
wherein in the third color filter, a fourth opening overlapping the light-receiving region and corresponding to the first opening, a fifth opening overlapping the first color light-emitting region and corresponding to the second opening, and a sixth opening overlapping the second color light-emitting region are defined.

17. The display device of claim 16, further comprising:
a sensing electrode disposed between the display element layer and the color filter layer and overlapping the non-light-emitting region,
wherein the sensing electrode has first to third mesh openings respectively corresponding to the first to third color light-emitting regions defined therein, and
wherein on a cross-section, the first mesh opening has a greater width than each of the second and fifth openings, the second mesh opening has a greater width than the sixth opening, and the third mesh opening has a greater width than the third opening.

18. The display device of claim 17,
wherein a fourth mesh opening corresponding to the light-receiving region is defined in the sensing electrode, and
wherein on a cross-section, the fourth mesh opening has a greater width than each of the first and fourth openings.

19. The display device of claim 1,
wherein when viewed on a plane, the first color light-emitting region has a smaller area than each of the second and third color light-emitting regions.

20. The display device of claim 1, further comprising:
a planarization layer disposed on the color filter layer to cover the color filters; and
a window disposed on the planarization layer.
